(19) United States
(12) Patent Application Publication
(10) Pub. No.: US 2025/0294977 A1
(43) Pub. Date: Sep. 18, 2025

(54) DISPLAY DEVICE HAVING REFLECTION CONTROL PATTERN

(71) Applicant: Samsung Display Co., LTD., Yongin-si (KR)

(72) Inventors: Hyeon Bum LEE, Yongin-si (KR); Hyoeng Ki KIM, Yongin-si (KR)

(21) Appl. No.: 18/829,572

(22) Filed: Sep. 10, 2024

(30) Foreign Application Priority Data
Mar. 13, 2024 (KR) 10-2024-0035307

(51) Int. Cl. H10K 59/126; H10K 59/122; H10K 59/38; H10K 59/40; H10K 59/80; H10K 102/00

(52) U.S. Cl. CPC H10K 59/126; H10K 59/122; H10K 59/38; H10K 59/40; H10K 59/8731; H10K 59/8791; H10K 2102/351

(57) ABSTRACT

A display device includes a pixel defining film which partitions a light emitting area and a non-light emitting area adjacent to each other within a display area a pixel electrode in the light emitting area and overlapped by the pixel defining film, a light emitting layer on the pixel electrode, a common electrode on the pixel defining film and the light emitting layer, an encapsulation layer on the common electrode, a reflection control layer on the encapsulation layer, and an uneven portion defined by a layer of protrusions between the pixel defining film and the reflection control layer, the protrusions overlapping the non-light emitting area and non-overlapping the light emitting area.

This application claims priority to Korean Patent Application No. 10-2024-0035307 filed on Mar. 13, 2024, and all the benefits accruing therefrom under 35 U.S.C. 119, the contents of which in its entirety are herein incorporated by reference.

### BACKGROUND

### 1. Field

The present disclosure relates to a display device.

### 2. Description of the Related Art

As an information society develops, the demand for a display device for displaying an image is increasing in various forms. For example, the display device has been applied to various electronic devices such as smartphones, digital cameras, laptop computers, navigation devices, and smart televisions.

The display device may be a flat panel display device such as a liquid crystal display device, a field emission display device, or a light emitting display device. The light emitting display device includes an organic light emitting display device including an organic light emitting element, an inorganic light emitting display device including an inorganic light emitting element such as an inorganic semiconductor, and a subminiature light emitting display device including a subminiature light emitting element.

The organic light emitting element may include two opposing electrodes and a light emitting layer interposed therebetween. The light emitting layer receives electrons and holes from the two electrodes and recombines the electronic and the holes to generate excitons, and the generated excitons change from an excited state to a ground state, thereby emitting light.

The organic light emitting display device including the organic light emitting element may be configured in a light weight and thin shape with low power consumption because of not requiring a light source such as a backlight unit, and has also attracted attention as a next-generation display device because of having high-quality characteristics such as a wide viewing angle, high luminance and contrast, and a fast response speed.

### SUMMARY

Aspects of the present disclosure provide a display device capable of reducing a reflectance of external light and improving black color.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a display device includes a substrate, a pixel electrode disposed on the substrate, a pixel defining film disposed to cover an edge of the pixel electrode and partitioning a light emitting area and a non-light emitting area, a light emitting layer disposed on the pixel electrode, a common electrode disposed on the pixel defining film and the light emitting layer, an encapsulation layer disposed on the common electrode, a reflection control layer disposed on the encapsulation layer, and an uneven portion disposed between the pixel defining film and the reflection control layer to overlap the non-light emitting area and non-overlap the light emitting area, and including a plurality of protrusions.

In an embodiment, the uneven portion is disposed directly on the pixel defining film.

In an embodiment, the reflection control layer includes a color filter overlapping the light emitting area and a light blocking pattern overlapping the non-light emitting area, the light blocking pattern partitions a light exit portion which overlaps the light emitting area, and the uneven portion overlaps the light exit portion.

In an embodiment, the uneven portion is disposed in an area where the light exit portion and the non-light emitting area overlap in plan view.

In an embodiment, the plurality of protrusions gradually decrease in area from a surface of the pixel defining film toward the reflection control layer.

In an embodiment, the pitch and width of the plurality of protrusions are each 0.5 to 2 μm.

In an embodiment, the display device further includes a spacer disposed between the pixel defining film and the common electrode and overlapping the non-light emitting area, where a thickness of the plurality of protrusions is smaller than a thickness of the spacer.

In an embodiment, the thickness of the plurality of protrusions is smaller than the thickness of the spacer by 1 μm or more.

In an embodiment, the plurality of protrusions are made of the same material as the spacer.

In an embodiment, the plurality of protrusions are made of the same material as the pixel defining film.

In an embodiment, the plurality of protrusions are formed integrally with the pixel defining film.

In an embodiment, the pixel defining film includes an inclined surface in contact with the pixel electrode, and the plurality of protrusions are disposed on the inclined surface.

In an embodiment, the encapsulation layer includes a first encapsulation layer, a second encapsulation layer disposed on the first encapsulation layer, and a third encapsulation layer disposed on the second encapsulation layer, the first encapsulation layer and the third encapsulation layer include an inorganic material, the second encapsulation layer includes an organic material, and the uneven portion is formed on the second encapsulation layer.

In an embodiment, the display device further includes a touch sensing layer disposed between the encapsulation layer and the reflection control layer, where the touch sensing layer includes a touch electrode and a touch insulating layer, and the uneven portion is formed on the touch insulating layer.

In an embodiment, the display device further includes a touch sensing layer disposed between the encapsulation layer and the reflection control layer.

According to an aspect of the present disclosure, a display device includes a substrate, a pixel electrode disposed on the substrate, a pixel defining film disposed to cover an edge of the pixel electrode and partitioning light emitting areas and a non-light emitting area, a light emitting layer disposed on the pixel electrode, a common electrode disposed on the pixel defining film and the light emitting layer, an encapsulation layer disposed on the common electrode, and a touch sensing layer disposed on the encapsulation layer and including a touch insulating layer on which a first uneven portion including a plurality of first protrusions is formed, where the first uneven portion overlaps the non-light emitting area and does not overlap the light emitting area.

In an embodiment, the first uneven portion further includes a first groove overlapping the non-light emitting area, and the plurality of first protrusions are disposed in the first groove.

In an embodiment, the first uneven portion is disposed to surround the light emitting area in plane view.

In an embodiment, the plurality of first protrusions include the same material as the touch insulating layer and are formed integrally with the touch insulating layer.

In an embodiment, the display device further includes a color filter layer disposed on the touch sensing layer and including a light blocking pattern overlapping the non-light emitting area and a color filter overlapping the light emitting area.

In an embodiment, the first uneven portion further includes a first groove overlapping the non-light emitting area, and the color filter includes a second uneven portion each including a second groove overlapping the first groove and a plurality of second protrusions overlapping the plurality of first protrusions.

In an embodiment, a width of the second groove is smaller than a width of the first groove, a depth of the second groove is smaller than a depth of the first groove, a width of the second protrusion is greater than a width of the first protrusion, and a height of the second protrusion is smaller than a height of the first protrusion.

In an embodiment, the display device further includes a polarizing member disposed on the touch sensing layer.

The display device according to an embodiment may reduce reflection of external light and improve black color by disposing a plurality of protrusions on at least one of a pixel defining film, a touch insulating layer, or color filters between a light blocking pattern and light emitting areas in plan view.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view of an electronic device according to an embodiment;

FIG. 2 is a perspective view illustrating a folded state of a foldable display device according to an embodiment;

FIG. 3 is a perspective view illustrating an unfolded state of the foldable display device of FIG. 2;

FIG. 4 is a perspective view illustrating a display device included in the electronic device according to an embodiment;

FIG. 5 is a cross-sectional side view of the display device of FIG. 4 viewed from a side;

FIG. 6 is a plan view illustrating a display layer of the display device according to an embodiment;

FIG. 7 is a plan view illustrating a touch sensing layer of the display device according to an embodiment;

FIG. 8 is a plan view illustrating an arrangement of light emitting areas in a display area of the display device according to an embodiment;

FIG. 9 is a plan view illustrating an arrangement of color filters disposed in the display area of FIG. 8;

FIG. 10 is a cross-sectional view taken along line X-X′ of FIG. 8;

FIG. 11 is a cross-sectional view illustrating a peripheral area of a third light emitting area of the display device according to an embodiment;

FIG. 12 is a plan view illustrating the peripheral area of the third light emitting area of the display device according to an embodiment;

FIG. 13 is a cross-sectional view illustrating a peripheral area of a third light emitting area of a display device according to an embodiment;

FIG. 14 is a cross-sectional view illustrating a peripheral area of a third light emitting area of a display device according to an embodiment;

FIG. 15 is a plan view illustrating the peripheral area of the third light emitting area of the display device according to an embodiment;

FIG. 16 is a cross-sectional view schematically illustrating a display device according to an embodiment;

FIG. 17 is a cross-sectional view illustrating a peripheral area of a third light emitting area of the display device according to an embodiment;

FIG. 18 is a cross-sectional view schematically illustrating a display device according to an embodiment;

FIG. 19 is a cross-sectional view illustrating a peripheral area of a third light emitting area of a display device according to an embodiment;

FIG. 20 is a plan view illustrating the peripheral area of the third light emitting area of FIG. 19;

FIG. 21 is a perspective view schematically illustrating a first groove and first protrusions of a touch insulating layer;

FIG. 22 is a cross-sectional view schematically illustrating a display device according to an embodiment;

FIG. 23 is a cross-sectional view schematically illustrating a display device according to an embodiment;

FIG. 24 is a cross-sectional view schematically illustrating a display device according to an embodiment;

FIG. 25 is a graph illustrating an SCE reflectance according to a wavelength band of display panel samples 1 to 4 according to a first experimental example;

FIG. 26 is a graph illustrating a reflection color of black of display panel samples 1 to 4 according to the first experimental example;

FIG. 27 is a graph illustrating an SCE color coordinate system of a display panel sample 5 according to a second experimental example;

FIG. 28 is a graph illustrating an SCE color coordinate system of a display panel sample 6 according to the second experimental example;

FIG. 29 is a graph illustrating an SCE color coordinate system of a display panel sample 7 according to the second experimental example; and

FIG. 30 is a graph illustrating a reflection color of black of display panel samples 5 to 7 according to the second experimental example.

### DETAILED DESCRIPTION

The present invention will now be described more fully hereinafter with reference to the accompanying drawings, in which embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being related to another element such as being “on” another layer or substrate, it can be directly on the other layer or substrate, or intervening layers may also be present. In contrast when a layer is referred to as being related to another element such as being “directly on” another layer or substrate, no other layer or substrate or intervening layers is present.

Like or same reference numbers indicate the same components throughout the specification. Within the Figures and the text of the disclosure, a reference number indicating a singular form of an element may also be used to reference a plurality of the singular element.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Each of the features of the various embodiments of the present disclosure may be combined or combined with each other, in part or in whole, and technically various interlocking and driving are possible. Each embodiment may be implemented independently of each other or may be implemented together in an association.

Hereinafter, embodiments of the present disclosure will be described with reference to the accompanying drawings.

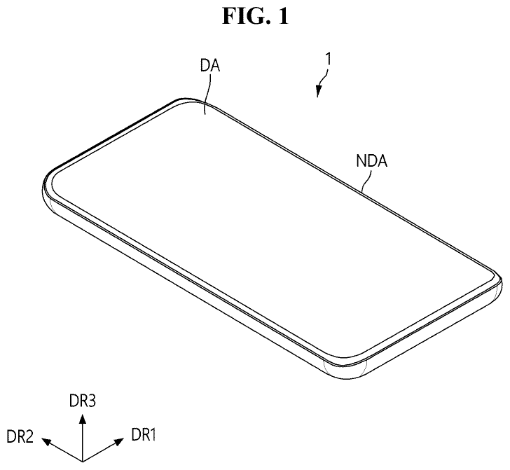

FIG. 1 is a schematic plan view of an electronic device 1 according to an embodiment.

Referring to FIG. 1, an electronic device 1 displays a moving image or a still image. The electronic device 1 may refer to any electronic device which provides a display screen at which an image is displayed. For example, the electronic device 1 may include televisions, laptop computers, monitors, billboards, Internet of things, mobile phones, smartphones, tablet personal computers (PCs), electronic watches, smartwatches, watch phones, head mounted displays, mobile communication terminals, electronic notebooks, electronic books, portable multimedia players (PMPs), navigation, game consoles, digital cameras, camcorders, and the like which provide the display screen.

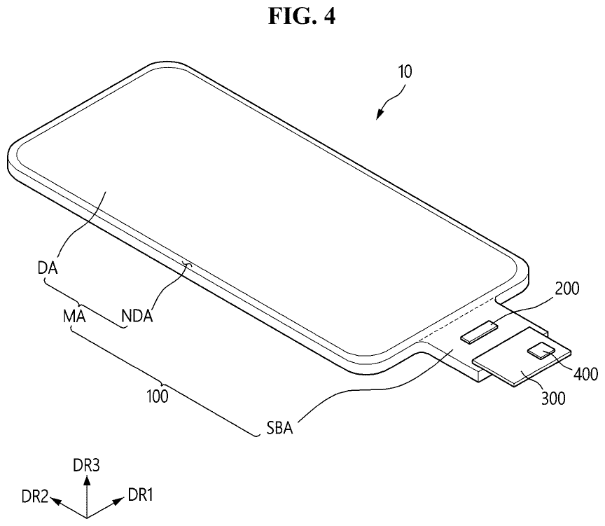

The electronic device 1 may include a display device (‘10’ in FIG. 4) which provides a display screen. Examples of the display device may include an inorganic light emitting diode display device, an organic light emitting display device, a quantum dot light emitting display device, a plasma display device, and a field emission display device. Hereinafter, it is illustrated that an organic light emitting diode display device is used as an example of the display device, but the present disclosure is not limited thereto and may also be applied to other display devices as long as the same technical idea is applicable thereto.

A shape of the electronic device 1 may be variously changed. For example, the electronic device 1 may have a planar shape such as a rectangle with a long width, a rectangle with a long length, a square, a quadrangle with rounded corners (vertices), other polygons, or a circle. A planar shape of a display area DA of the electronic device 1 may also be similar to an overall planar shape of the electronic device 1. In FIG. 1, the electronic device 1 having a rectangular planar shape with a long length (e.g., a major dimension) in a second direction DR2 is illustrated.

The electronic device 1 may include a display area DA and a non-display area NDA. The display area DA is an area (e.g., a planar area) in which a screen (e.g., an image) may be displayed, and the non-display area NDA is an area in which a screen is not displayed. The display area DA may also be referred to as an active area, and the non-display area NDA may also be referred to as a non-active area. The display area DA may generally occupy the center of the electronic device 1.

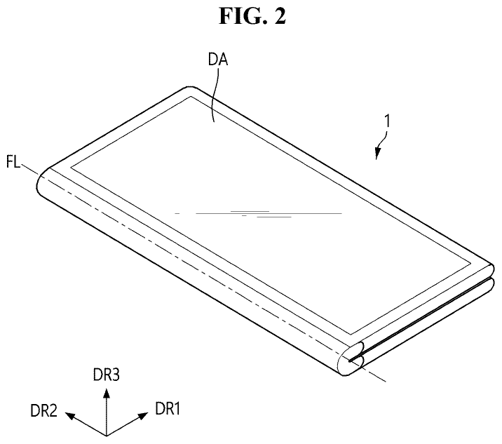

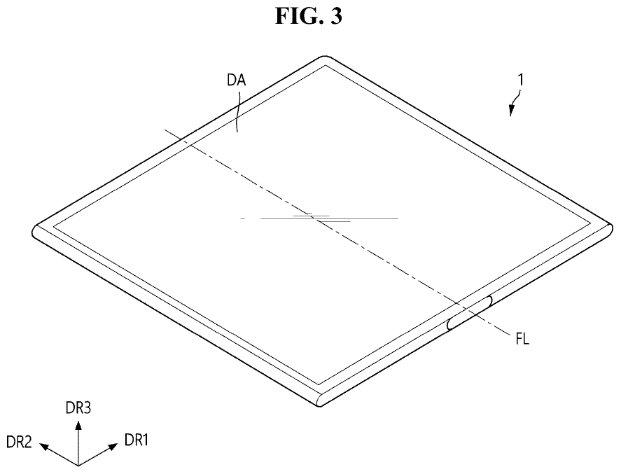

FIG. 2 is a perspective view illustrating a folded state of a foldable display device according to an embodiment. FIG. 3 is a perspective view illustrating an unfolded state of the foldable display device of FIG. 2.

Referring to FIGS. 2 and 3, the electronic device 1 according to an embodiment may be a foldable display device. The foldable electronic device 1 may be folded around or about a folding axis FL. The display area DA may be disposed on an outer side and/or inner side of the foldable electronic device 1 which is folded. In an embodiment, the foldable electronic device 1 of FIGS. 2 and 3 illustrates that the display area DA is disposed on the outer and inner sides, respectively.

The display area DA may be disposed on an outer side of the electronic device 1. An outer surface of the folded electronic device 1 may include the display area DA (e.g., an outer display area), and an inner surface of the unfolded electronic device 1 may include the display area DA (e.g., an inner display area).

FIG. 4 is a perspective view illustrating a display device 10 included in the electronic device 1 according to an embodiment.

Referring to FIG. 4, the electronic device 1 according to an embodiment may include a display device 10. The display device 10 may provide a screen displayed by the electronic device 1. The display device 10 may have a planar shape similar to that of the electronic device 1. For example, the display device 10 may have a shape similar to a rectangle having short sides in a first direction DR1 and long sides in a second direction DR2. The display device 10 and various components or layers thereof may be in a plane defined by the first direction DR1 and the second direction DR2 which cross each other. A corner where the short side in the first direction DR1 and the long side in the second direction DR2 meet each other may be rounded to have a curvature in the plan view, but is not limited thereto and may also be formed at a right angle. The planar shape of the display device 10 is not limited to the quadrangle, and may be formed similarly to other polygons, circles, or ovals.

The display device 10 may include a display panel 100, a display driver 200, a circuit board 300, and a touch driver 400.

The display panel 100 may include a main area MA and a sub-area SBA as a planar area of the display panel 100 excluding the main area MA. The main area MA may include a portion of the non-display area NDA and the sub-area SBA may include a remaining portion of the non-display area NDA. The display panel 100 may be bendable or foldable at the sub-area SBA. The sub-area SBA may be a foldable area (or folding area) of the display device 10. The main area MA may be a non-foldable (or non-folding area) of the display device 10.

The main area MA may include a display area DA including pixels displaying an image, and a non-display area NDA disposed adjacent to the display area DA, such as extending around the display area DA. The display area DA may emit light from a plurality of light emitting areas or a plurality of opening areas. For example, the display panel 100 may include a pixel circuit connected to a light emitting element and including switching elements, a pixel defining film defining the light emitting areas or the opening areas, and a self-light emitting element.

For example, the self-light emitting element as the light emitting element may include, but is not limited to, at least one of an organic light emitting diode (LED) including an organic light emitting layer, a quantum dot LED including a quantum dot light emitting layer, an inorganic LED including an inorganic semiconductor, and a micro LED.

The non-display area NDA may be an area outside the display area DA, that is, closer to an outer edge of the electronic device 1 than the display area DA. The non-display area NDA may be defined as an edge area of the main area MA of the display panel 100. A boundary may be defined between the display area DA and the non-display area NDA. The non-display area NDA may include a gate driver (not illustrated) supplying gate signals to gate lines, and fan-out lines (not illustrated) connecting the display driver 200 and the display area DA.

The sub-area SBA may be an area extending from one side of the main area MA. The sub-area SBA may include a flexible material which may be bent, folded, rolled, or the like. For example, when the display panel 100 is bent at the sub-area SBA, the sub-area SBA may overlap the main area MA in a thickness direction (e.g., a third direction DR3 which crosses each of the first direction DR1 and the second direction DR2).

The sub-area SBA may include the display driver 200 and a pad portion at which the display panel 100 is connected to the circuit board 300. In an embodiment, the sub-area SBA may be omitted, and the display driver 200 and the pad portion may be disposed in the non-display area NDA of the main area MA.

The display driver 200 may output signals and voltages for driving the display panel 100. The display driver 200 may supply data voltages to data lines. The display driver 200 may supply a power voltage to a power line and may supply a gate control signal to a gate driver. The display driver 200 may be formed (or provided) as an integrated circuit (IC) and mounted on the display panel 100 by a chip on glass (COG) method, a chip on plastic (COP) method, or an ultrasonic bonding method. For example, the display driver 200 may be disposed in the sub-area SBA, and may overlap the main area MA in the thickness direction by bending of the display panel 100 at the sub-area SBA. As another example, the display driver 200 may be mounted on the circuit board 300.

The circuit board 300 may be attached onto the display panel 100 at the pad portion thereof such as by using an anisotropic conductive film (ACF). Lead lines of the circuit board 300 may be electrically connected to the display panel 100 at the pad portion thereof. The circuit board 300 may be a flexible film such as a flexible printed circuit board, a printed circuit board, or a chip on film.

The touch driver 400 may be mounted on the circuit board 300. The touch driver 400 may be connected to a touch sensing unit of the display panel 100. The touch driver 400 may supply a touch driving signal to a plurality of touch electrodes of the touch sensing unit, and may sense an amount of change in capacitance between the plurality of touch electrodes. For example, the touch driving signal may be a pulse signal having a predetermined frequency. The touch driver 400 may calculate whether an input is made and input coordinates based on the amount of change in capacitance between the plurality of touch electrodes. The touch driver 400 may be formed as an integrated circuit (IC).

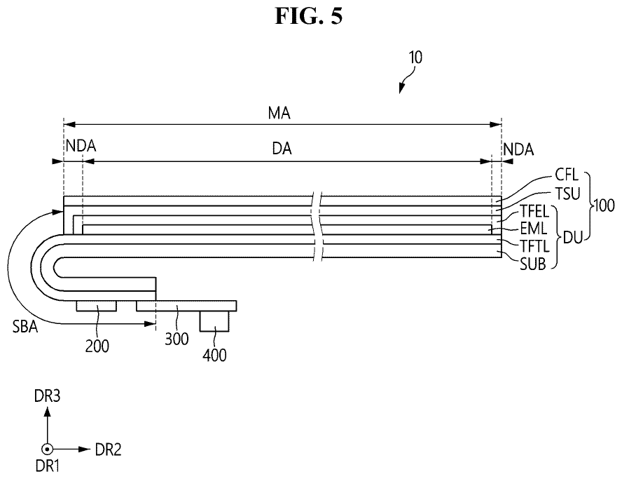

FIG. 5 is a cross-sectional view of the display device 10 of FIG. 4 viewed from a side. FIG. 5 is a cross-sectional view of the display device 10 of FIG. 4 which is bent at the sub-area SBA.

Referring to FIG. 5, the display panel 100 may include a display layer DU, a touch sensing layer TSU, and a color filter layer CFL. The display layer DU may include a substrate SUB, a thin film transistor layer TFTL as a circuit layer, a light emitting element layer EML, and an encapsulation layer TFEL.

The substrate SUB may be a base substrate or a base member. The substrate SUB may be a flexible substrate which may be bent, folded, rolled, or the like. For example, the substrate SUB may include a polymer resin such as polyimide (PI), but is not limited thereto. In an embodiment, the substrate SUB may include a glass material or a metal material.

A thin film transistor layer TFTL may be disposed on the substrate SUB. The thin film transistor layer TFTL may include a plurality of thin film transistors constituting a pixel circuit of pixels as a circuit layer. The thin film transistor layer TFTL may further include signal lines such as gate lines, data lines, power lines, gate control lines, fan-out lines connecting the display driver 200 and the data lines to each other, and lead lines connecting the display driver 200 and the pad portion to each other. Each of the thin film transistors of the circuit layer may include a semiconductor area, a source electrode, a drain electrode, and a gate electrode. For example, when the gate driver is formed on one side of the non-display area NDA of the display panel 100, the gate driver may include the thin film transistors.

The thin film transistor layer TFTL may be disposed in the display area DA, the non-display area NDA, and the sub-area SBA. The thin film transistors, the gate lines, the data lines, and the power lines of each of the pixels of the thin film transistor layer TFTL may be disposed in the display area DA. The gate control lines and the fan-out lines of the thin film transistor layer TFTL may be disposed in the non-display area NDA. The lead lines of the thin film transistor layer TFTL may be disposed in the sub-area SBA.

A light emitting element layer EML may be disposed on the thin film transistor layer TFTL and connected thereto. The light emitting element layer EML may include a plurality of light emitting elements which emit light, including a pixel electrode, a common electrode, and a light emitting layer, and a pixel defining film defining pixels. The plurality of light emitting elements of the light emitting element layer EML may be disposed in the display area DA.

In an embodiment, the light emitting layer may be an organic light emitting layer including an organic material. The light emitting layer may include a hole transporting layer, an organic light emitting layer, and an electron transporting layer. When the pixel electrode receives a voltage through the thin film transistor of the thin film transistor layer TFTL, and the common electrode receives a cathode voltage, holes and electrons may move to the organic light emitting layer through the hole transporting layer and the electron transporting layer, respectively, and may be bonded to each other in the organic light emitting layer to emit light.

In an embodiment, the light emitting element may include a quantum dot light emitting diode including a quantum dot light emitting layer, an inorganic light emitting diode including an inorganic semiconductor, or a micro light emitting diode.

The encapsulation layer TFEL may cover an upper surface and side surfaces of the light emitting element layer EML, and may protect the light emitting element layer EML. The encapsulation layer TFEL may include at least one inorganic film and at least one organic film for encapsulating the light emitting element layer EML.

The touch sensing layer TSU may be disposed on the encapsulation layer TFEL. The touch sensing layer TSU may include a plurality of touch electrodes for detecting an external input such as a user's touch, in a capacitance method, and touch lines connecting the plurality of touch electrodes and the touch driver 400. For example, the touch sensing layer TSU may sense the user's touch in a mutual capacitance method or a self-capacitance method.

In an embodiment, the touch sensing layer TSU may be disposed on a separate substrate disposed on the display layer DU. In this case, the substrate supporting the touch sensing layer TSU may function as a base member which encapsulates the display layer DU.

The plurality of touch electrodes of the touch sensing layer TSU may be disposed in a touch sensor area overlapping the display area DA. The touch lines of the touch sensing layer TSU may be disposed in a touch peripheral area overlapping the non-display area NDA.

The color filter layer CFL may be disposed on the touch sensing layer TSU. The color filter layer CFL may include a plurality of color filters corresponding to each of the plurality of light emitting areas. Each of the color filters may selectively transmit light of a specific wavelength and block or absorb light of a different wavelength from the specific wavelength. The color filter layer CFL may absorb a portion of light introduced from the outside of the display device 10 to reduce reflected light caused by external light. Therefore, the color filter layer CFL may serve as an anti-reflection layer and prevent color distortion caused by reflection of external light.

As the color filter layer CFL is directly disposed on the touch sensing layer TSU, the display device 10 may not require a separate substrate for the color filter layer CFL. Therefore, the display device 10 may have a relatively small overall thickness.

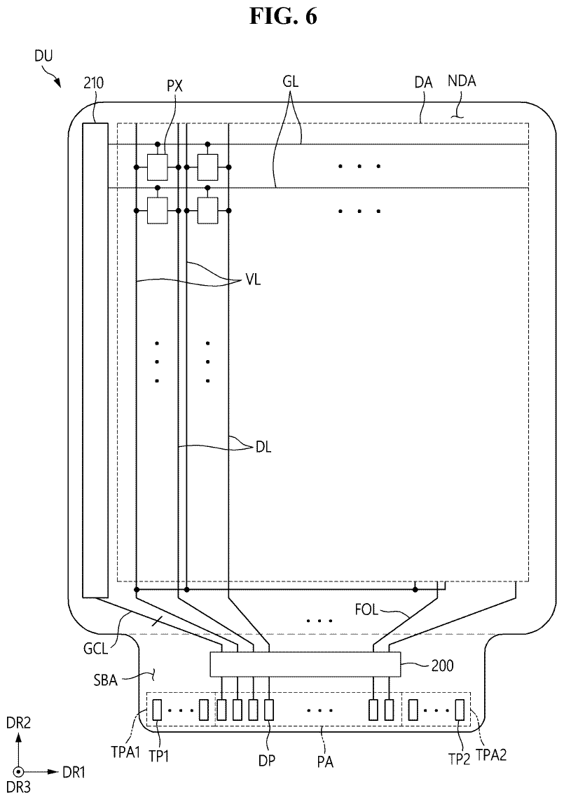

FIG. 6 is a plan view illustrating a display layer DU of the display device according to an embodiment.

Referring to FIG. 6, the display layer DU may include a display area DA and a non-display area NDA.

The display area DA may be disposed at a center of the display panel 100, such as being spaced apart from an outer edge of the display device 10. A plurality of pixels PX, a plurality of gate lines GL, a plurality of data lines DL, and a plurality of power lines VL may be disposed in the display area DA. Each of the plurality of pixels PX may be defined as a minimum unit emitting light.

The plurality of gate lines GL may supply a gate signal received from a gate driver 210 to the plurality of pixels PX. The plurality of gate lines GL may extend in the first direction DR1, and may be spaced apart from each other in the second direction DR2 intersecting the first direction DR1.

The plurality of data lines DL may supply the data voltage received from the display driver 200 to the plurality of pixels PX. The plurality of data lines DL may extend in the second direction DR2, and may be spaced apart from each other in the first direction DR1.

The plurality of power lines VL may supply the power voltage received from the display driver 200 to the plurality of pixels PX. Here, the power voltage may be at least one of a driving voltage, an initialization voltage, a reference voltage, and a low potential voltage. The plurality of power lines VL may extend in the second direction DR2, and may be spaced apart from each other in the first direction DR1.

The non-display area NDA may surround the display area DA. The gate driver 210, fan-out lines FOL, and gate control lines GCL may be disposed in the non-display area NDA. The gate driver 210 may generate a plurality of gate signals based on the gate control signal, and may sequentially supply the plurality of gate signals to the plurality of gate lines GL according to a set order.

The fan-out lines FOL may extend from the display driver 200 to the display area DA. The fan-out lines FOL may supply the data voltages received from the display driver 200 to the plurality of data lines DL.

The gate control line GCL may extend from the display driver 200 to the gate driver 210. The gate control line GCL may supply the gate control signal received from the display driver 200 to the gate driver 210.

The sub-area SBA may include a display driver 200, a pad area PA, and touch pad areas including first and second touch pad areas TPA1 and TPA2.

The display driver 200 may output signals and voltages for driving the display panel 100 to the fan-out lines FOL. The display driver 200 may supply the data voltage to the data lines DL through the fan-out lines FOL. The data voltage may be supplied to the plurality of pixels PX and may control luminance of the plurality of pixels PX. The display driver 200 may supply the gate control signal to the gate driver 210 through the gate control line GCL.

The pad area PA, the first touch pad area TPA1, and the second touch pad area TPA2 may be disposed along an edge of the sub-area SBA. The circuit board 300 may be electrically connected to the display panel 100 at the pad area PA, the first touch pad area TPA1, and the second touch pad area TPA2, such as by using an anisotropic conductive film or a material such as a self assembly anisotropic conductive paste (SAP). The first touch pad area TPA1 includes a first touch pad portion TP1 as a first touch pad, and the second touch pad area TPA2 includes a second touch pad portion TP2 as a second touch pad, and the first touch pad area TPA1 and the second touch pad area TPA2 may electrically connect the display panel 100 to the circuit board 300.

The pad area PA may include a plurality of display pad portions DP as display pads. The plurality of display pad portions DP may connect the display panel 100 to a graphics system through the circuit board 300. The plurality of display pad portions DP may connect the display panel 100 to the circuit board 300 to receive digital video data, and may supply the digital video data to the display driver 200.

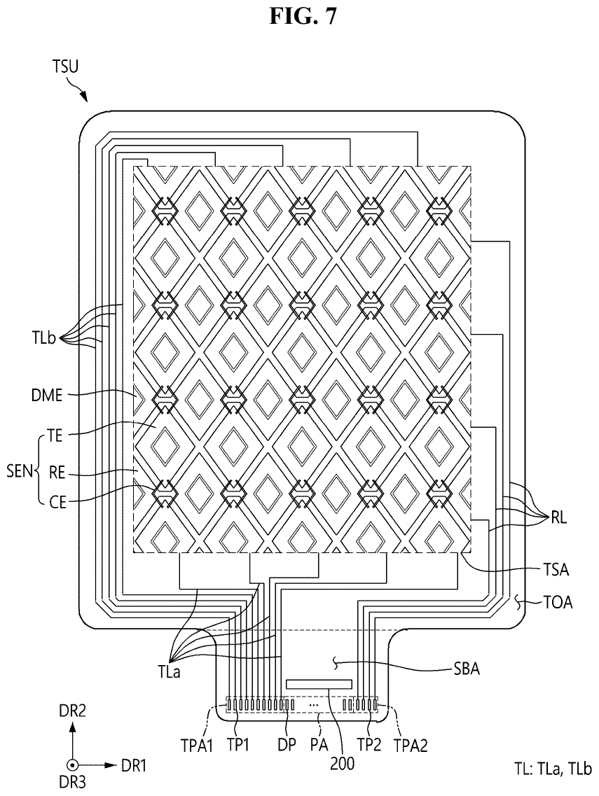

FIG. 7 is a plan view illustrating a touch sensing layer TSU of the display device 10 according to an embodiment.

Referring to FIG. 7, the touch sensing layer TSU may include a touch sensor area TSA at which a user's touch is sensed, and a touch peripheral area TOA which is disposed adjacent to and/or around the touch sensor area TSA. The touch sensor area TSA may be disposed in the display area DA of the display device 10, and the touch peripheral area TOA may be disposed in the non-display area NDA of the display device 10.

The touch sensor area TSA may include a plurality of touch electrodes SEN and a plurality of dummy electrodes DME. The plurality of touch electrodes SEN may form mutual capacitance or self capacitance to sense an external input such as a touch of an object or a person. The plurality of touch electrodes SEN may include a plurality of driving electrodes TE, a plurality of sensing electrodes RE, and a bridge electrode CE.

The plurality of driving electrodes TE may be arranged in the first direction DR1 and the second direction DR2. The plurality of driving electrodes TE may be spaced apart from each other in the first direction DR1 and the second direction DR2. The driving electrodes TE adjacent to each other in the second direction DR2 may be electrically connected to each other through the bridge electrode CE.

The plurality of driving electrodes TE may be connected to a first touch pad portion TP1 through a driving line TL. The driving line TL may include a lower driving line TLa and an upper driving line TLb. For example, the driving electrodes TE disposed on a lower side of the touch sensor area TSA may be connected to the first touch pad portion TP1 through the lower driving line TLa, and the driving electrodes TE disposed on an upper side of the touch sensor area TSA may be connected to the first touch pad portion TP1 through the upper driving line TLb. The lower driving line TLa may pass through a lower side of the touch peripheral area TOA and extend to the first touch pad portion TP1. The upper driving line TLb may extend to the first touch pad portion TP1 via upper, left, and lower sides of the touch peripheral area TOA. The first touch pad portion TP1 may be connected to the touch driver 400 through the circuit board 300.

The bridge electrode CE may be bent at least once along the plan view. For example, the bridge electrode CE may have a clamp shape (“<” or “>”), but a planar shape of the bridge electrode CE is not limited thereto. The driving electrodes TE adjacent to each other in the second direction DR2 may be connected to each other by a plurality of bridge electrodes CE, and even if any one of the bridge electrodes CE is disconnected, the driving electrodes TE may be stably connected to each other through the remaining bridge electrodes CE. The driving electrodes TE adjacent to each other may be connected to each other by two bridge electrodes CE, but the number of bridge electrodes CE is not limited thereto.

The bridge electrodes CE may be disposed on a layer different from that of the plurality of driving electrodes TE and the plurality of sensing electrodes RE. As being on a same layer, elements may be formed in a same process and/or include a same material as each other, elements may be respective portions of a same material layer to be considered in a same layer as each other, elements may be on a same layer by forming an interface with a same underlying or overlying layer, etc., without being limited thereto.

The sensing electrodes RE adjacent to each other in the first direction DR1 may be electrically connected to each other through a connection portion disposed on the same layer as the plurality of driving electrodes TE or the plurality of sensing electrodes RE, and the driving electrodes TE adjacent to each other in the second direction DR2 may be electrically connected to each other through the bridge electrode CE disposed on the layer different from the plurality of driving electrodes TE or the plurality of sensing electrodes RE. Therefore, even if the bridge electrodes CE overlap the plurality of sensing electrodes RE in the thickness direction, the plurality of driving electrodes TE and the plurality of sensing electrodes RE may be insulated (e.g., electrically insulated) from each other. Mutual capacitance may be formed between the driving electrode TE and the sensing electrode RE in detecting an external input to the touch sensing layer TSU.

The plurality of sensing electrodes RE may extend in the first direction DR1 and may be spaced apart from each other in the second direction DR2. The plurality of sensing electrodes RE may be arranged in the first direction DR1 and the second direction DR2, and the sensing electrodes RE adjacent to each other in the first direction DR1 may be electrically connected to each other through the connection portion.

The plurality of sensing electrodes RE may be connected to the second touch pad portion TP2 through a sensing line RL. For example, the sensing electrodes RE disposed on the left side of the touch sensor area TSA may be connected to the second touch pad portion TP2 through the sensing line RL. The sensing line RL may extend to the second touch pad portion TP2 via the right and lower sides of the touch peripheral area TOA. The second touch pad portion TP2 may be connected to the touch driver 400 through the circuit board 300.

Each of the plurality of dummy electrodes DME may be surrounded by the driving electrode TE or the sensing electrode RE. Each of the plurality of dummy electrodes DME may be spaced apart from and insulated from the driving electrode TE or the sensing electrode RE. Accordingly, the dummy electrode DME may be electrically floating. The dummy electrode DME may be a discrete pattern, such as having an island shape to be electrically insulated from the tough electrodes SEN.

The pad area PA, the first touch pad area TPA1, and the second touch pad area TPA2 may be disposed at an edge of the sub-area SBA. The pad area PA, the first touch pad area TPA1, and the second touch pad area TPA2 may electrically connect the touch sensing layer TSU to the circuit board 300 using a low-resistance, high-reliability material such as an anisotropic conductive film or self assembly anisotropic conductive paste (SAP).

In a direction along the edge of the sub-area SBA, the first touch pad area TPA1 may be disposed on one side of the pad area PA and may include a plurality of first touch pad portions TP1. The plurality of first touch pad portions TP1 may be electrically connect the touch sensing layer TSU to the touch driver 400 disposed on the circuit board 300. The plurality of first touch pad portions TP1 may supply a touch driving signal to the plurality of driving electrodes TE through the plurality of driving lines TL.

In the direction along the edge of the sub-area SBA, the second touch pad area TPA2 may be disposed on the other side of the pad area PA and may include a plurality of second touch pad portions TP2. The plurality of second touch pad portions TP2 may be electrically connect the touch sensing layer TSU to the touch driver 400 disposed on the circuit board 300. The touch driver 400 may receive a touch sensing signal through the plurality of sensing lines RL connected to the plurality of second touch pad portions TP2, and may sense a change in mutual capacitance between the driving electrode TE and the sensing electrode RE.

In an embodiment, the touch driver 400 may supply a touch driving signal to each of the plurality of driving electrodes TE and the plurality of sensing electrodes RE, and may receive a touch sensing signal from each of the plurality of driving electrodes TE and the plurality of sensing electrodes RE. The touch driver 400 may sense an amount of (electrical) charge change of each of the plurality of driving electrodes TE and the plurality of sensing electrodes RE based on the touch sensing signal.

It is illustrated in FIG. 7 that the plurality of touch electrodes SEN of the touch sensing layer TSU have a diamond-shaped structure in the plan view and are connected in the first and second directions DR1 and DR2, but the present disclosure is not limited thereto, and the plurality of touch electrodes SEN may be formed in a mesh shape. For the mesh shape, solid portions of the touch electrodes SEN are spaced apart from each other to define an opening between the solid portions. Together, the solid portions and the openings define the mesh shape.

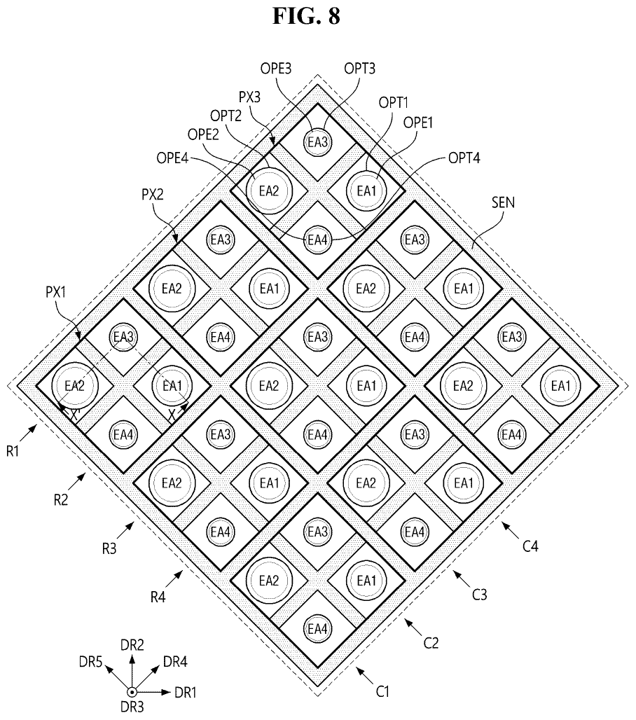

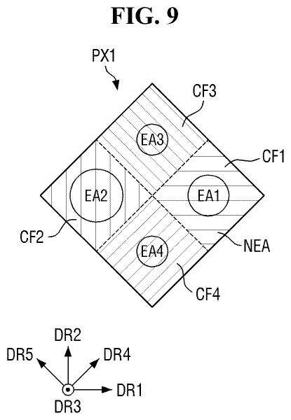

FIG. 8 is a plan view illustrating an arrangement of light emitting areas in a display area DA of the display device 10 according to an embodiment. FIG. 9 is a plan view illustrating an arrangement of color filters disposed in the display area DA of FIG. 8.

Referring to FIGS. 8 and 9, the display device 10 may include a plurality of pixels PX1, PX2, and PX3 disposed in the display area DA. Light emitting areas EA1, EA2, EA3, and EA4 and a non-light emitting area NEA may be disposed in each of the pixels PX1, PX2, and PX3. The plurality of pixels PX1, PX2, and PX3 may be arranged in (or along) a fourth direction DR4 and a fifth direction DR5 each inclined relative to the first direction DR1 and the second direction DR2. The first pixel PX1, the second pixel PX2, and the third pixel PX3 may be alternately and/or repeatedly disposed along the fourth direction DR4 and the fifth direction DR5. For example, the first pixel PX1, the second pixel PX2 and the third pixel PX3 may be arranged in order in the fourth direction DR4 and the fifth direction DR5. The plurality of pixels PX1, PX2, and PX3 may be disposed in a PenTile™ type, for example, a diamond PenTile™ type in the display area DA. However, the arrangement of the pixels PX1, PX2, and PX3 is not limited to that illustrated in FIGS. 8 and 9. In some embodiments, the plurality of pixels PX1, PX2, and PX3 may be arranged in a linear or island-like pattern.

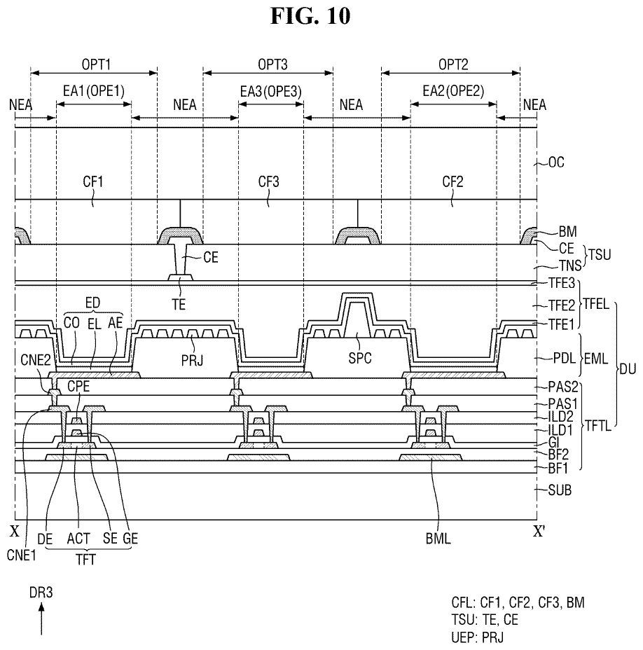

The light emitting areas EA1, EA2, EA3, and EA4 within of each of the pixels PX1, PX2, and PX3 may include a first light emitting area EA1, a second light emitting area EA2, a third light emitting area EA3, and a fourth light emitting area EA4 which emit light of different colors from each other. Unlike the first light emitting area EA1 and the second light emitting area EA2, the third light emitting area EA3 and the fourth light emitting area EA4 may emit light of the same color. The first to fourth light emitting areas EA1, EA2, EA3, and EA4 may variously emit red, blue, or green light, and the color of light emitted from each of the light emitting areas EA1, EA2, EA3, and EA4 may be different depending on the type of light emitting element (‘ED’ in FIG. 10) disposed on the light emitting element layer EML, which will be described later. In an embodiment, the first light emitting area EA1 may emit first light of a red color, the second light emitting area EA2 may emit second light of a blue color, and the third light emitting area EA3 and the fourth light emitting area EA4 may emit third light of a green color. However, the present disclosure is not limited thereto.

The plurality of light emitting areas EA1, EA2, EA3, and EA4 may be disposed in a PenTile™ type, for example, a diamond PenTile™ type. For example, within each of the pixels PX1, PX2, and PX3, the first light emitting area EA1 and the second light emitting area EA2 may be disposed to be spaced apart from each other in the first direction DR1, and the third light emitting area EA3 and the fourth light emitting area EA4 may be disposed to be spaced apart from each other in the second direction DR2. The first light emitting area EA1 may be disposed to be spaced apart from the third light emitting area EA3 in the fifth direction DR5, and may be disposed to be spaced apart from the fourth light emitting area EA4 in the fourth direction DR4. The second light emitting area EA2 may be disposed to be spaced apart from the third light emitting area EA3 in the fourth direction DR4, and may be disposed to be spaced apart from the fourth light emitting area EA4 in the fifth direction DR5.

In the plurality of pixels PX1, PX2, and PX3, the plurality of first to fourth light emitting areas EA1, EA2, EA3, and EA4 may be variously alternately and/or repeatedly disposed in the fourth direction DR4 or the fifth direction DR5. For example, the plurality of light emitting areas EA1, EA2, EA3, and EA4 may be disposed in rows R1, R2, R3, and R4 arranged along the fourth direction DR4 and columns C1, C2, C3, and C4 arranged along the fifth direction DR5. In odd number rows of the first row R1 and the third row R3, the second light emitting area EA2 and the third light emitting area EA3 may be disposed to alternate with each other along the fourth direction DR4. In even number rows of the second row R2 and the fourth row R4, the first light emitting area EA1 and the fourth light emitting area EA4 may be disposed to alternate with each other along the fourth direction DR4. In odd number columns of the first column C1 and the third column C3, the second light emitting area EA2 and the fourth light emitting area EA4 may be disposed to alternate with each other along the fifth direction DR5. In even number columns the second column C2 and the fourth column C4, the first light emitting area EA1 and the third light emitting area EA3 may be disposed to alternate with each other along the fourth direction DR4.

Alternatively, the plurality of light emitting areas EA1, EA2, EA3, and EA4 may be arranged along the first direction DR1 or the second direction DR2. The first light emitting area EA1 and the second light emitting area EA2 may be disposed to alternate with each other along the first direction DR1 and the second direction DR2. The third light emitting area EA3 and the fourth light emitting area EA4 may be disposed to alternate with each other along the first direction DR1 and the second direction DR2.

Each of the first to fourth light emitting areas EA1, EA2, EA3, and EA4 may be defined by pixel openings including a plurality of openings OPE1, OPE2, OPE3, and OPE4 formed in (or by) a pixel defining film (‘PDL’ in FIG. 10) of the light emitting element layer EML, which will be described later. For example, the first light emitting area EA1 may be defined by a first opening OPE1 of the pixel defining film, the second light emitting area EA2 may be defined by a second opening OPE2 of the pixel defining film, the third light emitting area EA3 may be defined by a third opening OPE3 of the pixel defining film, and the fourth light emitting area EA4 may be defined by a fourth opening OPE4 of the pixel defining film.

In an embodiment, the areas or sizes of the first to fourth light emitting areas EA1, EA2, EA3, and EA4 in the plan view (e.g., a planar area or planar size) may be different. In the embodiment of FIG. 8, the area of the second light emitting area EA2 may be greater than the areas of the first light emitting area EA1, the third light emitting area EA3, and the fourth light emitting area EA4, and the area of the first light emitting area EA1 may be greater than the areas of the third light emitting area EA3 and the fourth light emitting area EA4. The areas of the light emitting areas EA1, EA2, EA3, and EA4 may vary according to the corresponding sizes of the openings OPE1, OPE2, OPE3, and OPE4 formed in the pixel defining film.

Intensities of light emitted from the light emitting areas EA1, EA2, EA3, and EA4 may vary depending on the areas of the light emitting areas EA1, EA2, EA3, and EA4, and a color of a screen displayed on the display device 10 or the electronic device 1 may be controlled by adjusting the areas of the light emitting areas EA1, EA2, EA3, and EA4. It is illustrated in the embodiment of FIG. 8 that the area of the second light emitting area EA2 is the largest, but the present disclosure is not limited thereto. The areas of the light emitting areas EA1, EA2, EA3, and EA4 may be freely adjusted according to the color of the screen required by the display device 10 and the electronic device 1. In addition, the areas of the light emitting areas EA1, EA2, EA3, and EA4 may be related to light efficiency and lifespan of the light emitting element ED, and may have a trade-off relationship with reflection of external light at the various light emitting areas. The areas of the light emitting areas EA1, EA2, EA3, and EA4 may be adjusted in consideration of the above-mentioned matters.

In addition, the plurality of openings OPE1, OPE2, OPE3, and OPE4 and a plurality of light exit portions OPT1, OPT2, OPT3, and OPT4 are exemplarily illustrated and explained in a circular shape, but are not limited thereto, and may be applied in various ways, such as an oval shape or a polygonal structure with curved edges.

Each of the plurality of pixels PX1, PX2, and PX3 may include the first to fourth light emitting areas EA1, EA2, EA3, and EA4 disposed adjacent to each other and may express a white grayscale. However, the present disclosure is not limited thereto, and a combination of the light emitting areas EA1, EA2, EA3, and EA4 together constituting one pixel group may be variously modified according to the arrangement of the light emitting areas EA1, EA2, EA3, and EA4, and the colors of the light emitted therefrom.

The non-light emitting area NEA may be the remaining (planar) area excluding planar areas the light emitting areas EA1, EA2, EA3, and EA4. The non-light emitting area NEA may be disposed between the light emitting areas EA1, EA2, EA3, and EA4. The non-light emitting area NEA may overlap the pixel defining film. For example, the area of the non-light emitting area NEA may be the same as the area of the pixel defining film.

The display device 10 may include a plurality of color filters CF1, CF2, CF3, and CF4 disposed on the light emitting areas EA1, EA2, EA3 and EA4, respectively. The plurality of color filters CF1, CF2, CF3, and CF4 may be disposed to correspond to the light emitting areas EA1, EA2, EA3, and EA4. For example, the color filters CF1, CF2, CF3, and CF4 may be disposed to overlap the light emitting areas EA1, EA2, EA3, and EA4, or the openings OPE1, OPE2, OPE3, and OPE4, or the plurality of light exit portions OPT1, OPT2, OPT3, and OPT4. The plurality of light exit portions OPT1, OPT2, OPT3, and OPT4 may be partitioned by a light blocking pattern (‘BM’ in FIG. 10), may be formed to overlap the openings OPE1, OPE2, OPE3, and OPE4, and may form a light exit area where the light emitted from the light emitting areas EA1, EA2, EA3, and EA4 is emitted. The color filters CF1, CF2, CF3, and CF4 may have a greater (planar) area than the light exit portions OPT1, OPT2, OPT3, and OPT4 and the openings OPE1, OPE2, OPE3, and OPE4, and may completely cover the light exit area formed by the light exit portions OPT1, OPT2, OPT3, and OPT4.

The color filters CF1, CF2, CF3, and CF4 may be disposed to correspond to different light emitting areas EA1, EA2, EA3, and EA4, respectively. The color filters CF1, CF2, CF3, and CF4 may include a first color filter CF1, a second color filter CF2, a third color filter CF3, and a fourth color filter CF4. The color filters CF1, CF2, CF3, and CF4 may include a colorant such as a dye or pigment which absorbs light in a wavelength band other than light in a specific wavelength band, and may be disposed to correspond to the colors of light emitted from the light emitting areas EA1, EA2, EA3, and EA4.

For example, the first color filter CF1 may be a red color filter which is disposed to overlap the first light emitting area EA1 and transmits only first light of a red color. The second color filter CF2 may be a blue color filter which is disposed to overlap the second light emitting area EA2 and transmits only second light of a blue color. The third color filter CF3 may be disposed to overlap the third light emitting area EA3, and the fourth color filter CF4 may be disposed to overlap the fourth light emitting area EA4. The third color filter CF3 and the fourth color filter CF4 may be green color filters which transmit only light of a green color.

The first color filter CF1 may be disposed to overlap the first light emitting area EA1 and not overlap the second light emitting area EA2, the third light emitting area EA3, and the fourth light emitting area EA4. The second color filter CF2 may be disposed to overlap the second light emitting area EA2 and not overlap the first light emitting area EA1, the third light emitting area EA3, and the fourth light emitting area EA4. The third color filter CF3 may be disposed to overlap the third light emitting area EA3 and not overlap the first light emitting area EA1, the second light emitting area EA2, and the fourth light emitting area EA4. The fourth color filter CF4 may be disposed to overlap the fourth light emitting area EA4 and not overlap the first light emitting area EA1, the second light emitting area EA2, and the third light emitting area EA3. As not overlapping, elements may be adjacent to each other along a plane or spaced apart from each other along the plane.

The display device 10 may control a color of reflected light caused by external light by adjusting the arrangement, shape, and area of the color filters CF1, CF2, CF3, and CF4 in plan view. In an embodiment, for example, the reflection control layer includes a color filter which overlaps the light emitting area, and a light blocking layer including a light blocking pattern BM which overlaps the non-light emitting area and partitions a light exit opening (e.g., a light exit portion) of the light blocking layer which overlaps the light emitting area. Here, the protrusions PRJ of the uneven portion UEP further overlap the light exit opening of the light blocking layer.

A solid material portion of the touch electrode SEN may be disposed between the light emitting areas EA1, EA2, EA3, and EA4. The touch electrode SEN may be disposed to lengthwise extend in the fourth direction DR4 and the fifth direction DR5, and may not overlap and be spaced apart from the light emitting areas EA1, EA2, EA3, and EA4. The touch electrode SEN may be disposed to overlap a solid material portion of a pixel defining film (‘PDL’ in FIG. 10) including the openings OPE1, OPE2, OPE3, and OPE4, and a solid material portion of a light blocking layer (‘BM’ in FIG. 10) including the plurality of light exit portions OPT1, OPT2, OPT3, and OPT4 described later. Although the touch electrode SEN is briefly illustrated in FIG. 8, the touch electrode SEN may be either the touch driving electrode TE or the sensing electrode RE of FIG. 7.

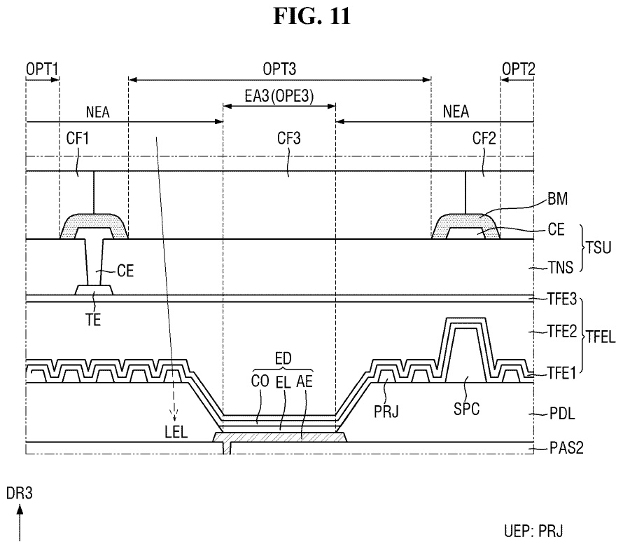

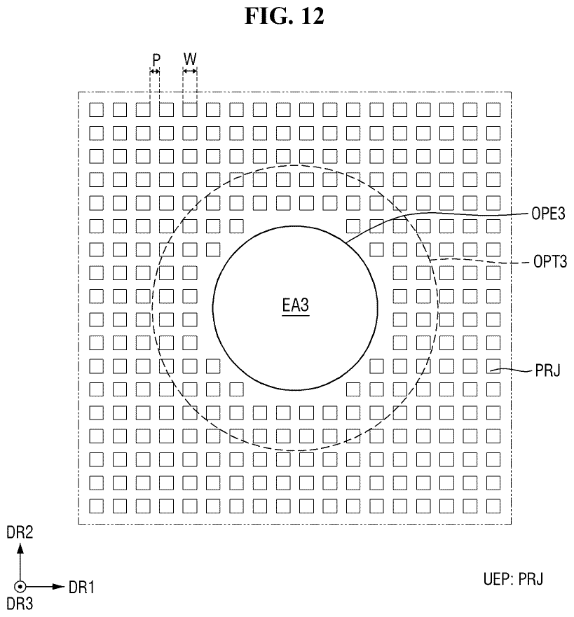

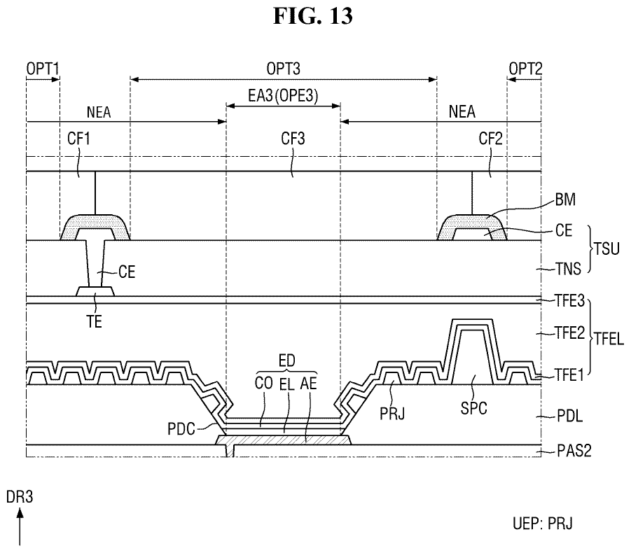

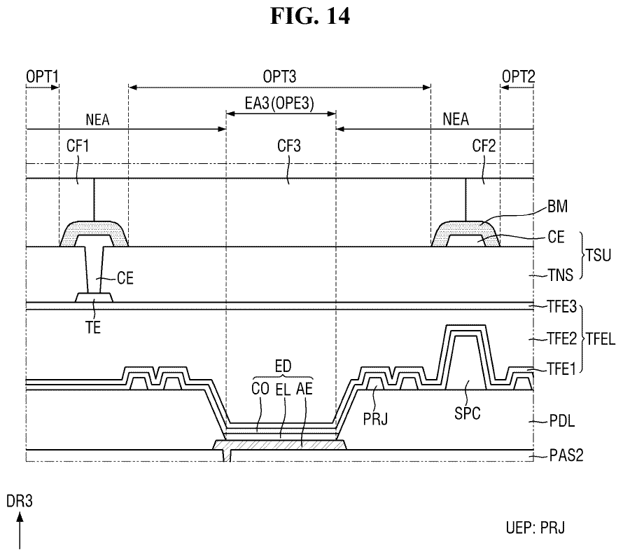

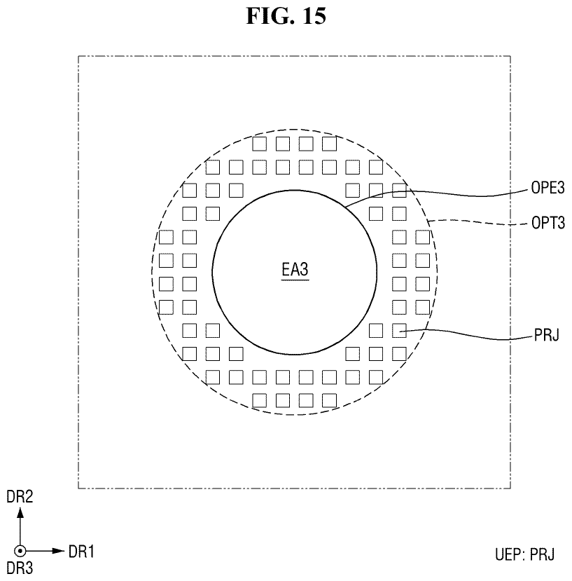

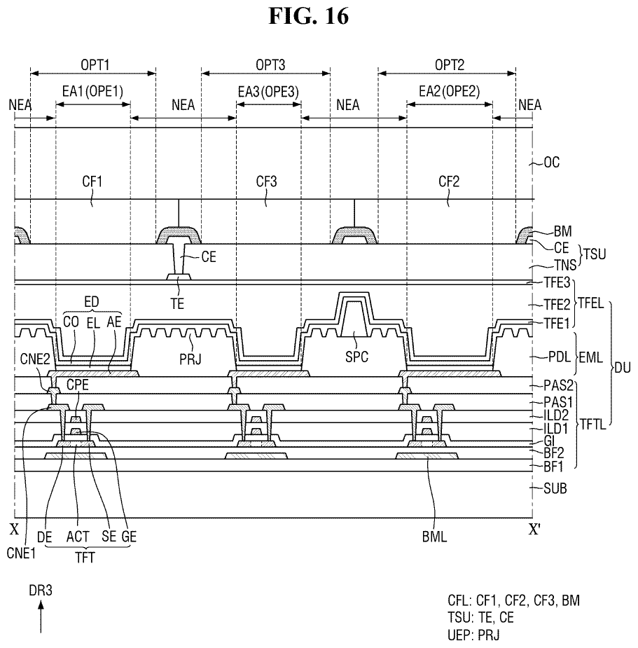

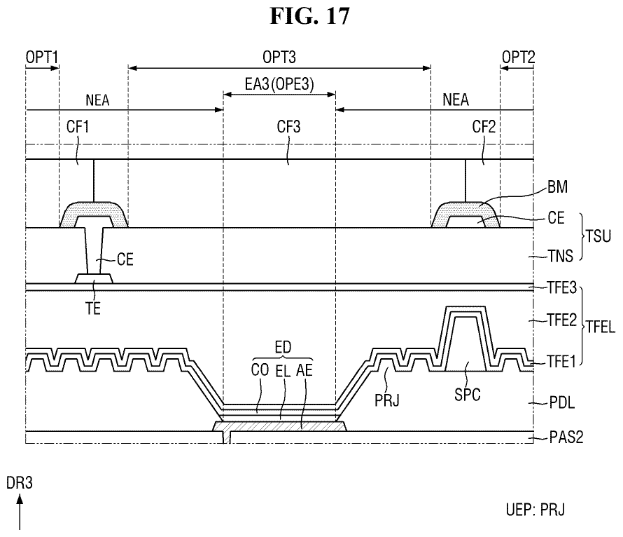

FIG. 10 is a cross-sectional view taken along line X-X′ of FIG. 8. FIG. 11 is an enlarged cross-sectional view illustrating a peripheral area of a third light emitting area EA3 of the display device 10 according to an embodiment. FIG. 12 is an enlarged plan view illustrating the peripheral area of the third light emitting area EA3 of the display device 10 according to an embodiment. FIG. 13 is an enlarged cross-sectional view illustrating a peripheral area of a third light emitting area EA3 of a display device 10 according to an embodiment. FIG. 14 is an enlarged cross-sectional view illustrating a peripheral area of a third light emitting area EA3 of a display device 10 according to an embodiment. FIG. 15 is an enlarged plan view illustrating the peripheral area of the third light emitting area EA3 of the display device 10 according to an embodiment. FIG. 16 is a cross-sectional view taken along line X-X′ of FIG. 8. FIG. 17 is an enlarged cross-sectional view illustrating a peripheral area of a third light emitting area EA3 of the display device 10 according to an embodiment.

Referring to FIGS. 10 to 12 together with FIGS. 8 and 9, the display panel 100 of the display device 10 according to an embodiment may include a display layer DU, a touch sensing layer TSU, a color filter layer CFL, and an overcoat layer OC. The display layer DU may include a substrate SUB, a thin film transistor layer TFTL, a light emitting element layer EML, and an encapsulation layer TFEL.

The substrate SUB may be a base substrate or a base member. The substrate SUB may be a flexible substrate which may be bent, folded, rolled, or the like. For example, the substrate SUB may include a polymer resin such as polyimide PI, but is not limited thereto. As another example, the substrate SUB may include a glass material or a metal material.

The thin film transistor layer TFTL may include a first buffer layer BF1, a lower metal layer BML, a second buffer layer BF2, a thin film transistor TFT, a gate insulating layer GI, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2.

The first buffer layer BF1 may be disposed on the substrate SUB. The first buffer layer BF1 may include an inorganic film capable of preventing permeation of air or moisture. For example, the first buffer layer BF1 may include a plurality of inorganic films alternately stacked.

The lower metal layer BML may be disposed as a pattern or plural patterns on the first buffer layer BF1. For example, the lower metal layer BML may be formed of a single layer or a multi-layer made of (or including) any one of molybdenum (Mo), aluminum (Al), chromium (Cr), gold (Au), titanium (Ti), nickel (Ni), neodymium (Nd), tantalum (Ta), and copper (Cu), or an alloy thereof.

The second buffer layer BF2 may cover the first buffer layer BF1 and the lower metal layer BML. The second buffer layer BF2 may include an inorganic film capable of preventing permeation of air or moisture. For example, the second buffer layer BF2 may include a plurality of inorganic films alternately stacked.

The thin film transistor TFT may be disposed on the second buffer layer BF2, and may constitute a structure in a pixel circuit of each of the plurality of pixels. For example, the thin film transistor TFT may be a driving transistor or a switching transistor of the pixel circuit. The thin film transistor TFT may include a semiconductor layer ACT, a source electrode SE, a drain electrode DE, and a gate electrode GE.

The semiconductor layer ACT may be disposed on the second buffer layer BF2. The semiconductor layer ACT may overlap the lower metal layer BML and the gate electrode GE in the thickness direction, and may be insulated from the gate electrode GE by the gate insulating layer GI. In a portion of the semiconductor layer ACT, a material of the semiconductor layer ACT may become a conductor (e.g., electrically conductive) to form the source electrode SE and the drain electrode DE.

The gate electrode GE may be disposed on the gate insulating layer GI. The gate electrode GE may overlap the semiconductor layer ACT with the gate insulating layer GI interposed therebetween.

The gate insulating layer GI may be disposed on the semiconductor layer ACT. For example, the gate insulating layer GI may cover the semiconductor layer ACT and the second buffer layer BF2, and may insulate the semiconductor layer ACT and the gate electrode GE from each other. The gate insulating layer GI may include (or define) a contact hole through which the first connection electrode CNE1 penetrates the gate insulating layer GI.

The first interlayer insulating layer ILD1 may cover the gate electrode GE and the gate insulating layer GI. The first interlayer insulating layer ILD1 may include a contact hole through which the first connection electrode CNE1 penetrates the first interlayer insulating layer ILD1. The contact hole of the first interlayer insulating layer ILD1 may be connected to the contact hole of the gate insulating layer GI and a contact hole of the second interlayer insulating layer ILD2, such as to form a through-hole or a single contact hole.

The capacitor electrode CPE may be disposed on the first interlayer insulating layer ILD1. The capacitor electrode CPE may overlap the gate electrode GE in the thickness direction. The capacitor electrode CPE and the gate electrode GE may form a capacitance (e.g., an electrical capacitance).

The second interlayer insulating layer ILD2 may cover the capacitor electrode CPE and the first interlayer insulating layer ILD1. The second interlayer insulating layer ILD2 may include a contact hole through which the first connection electrode CNE1 penetrates the second interlayer insulating layer ILD2. The contact hole of the second interlayer insulating layer ILD2 may be connected to the contact hole of the first interlayer insulating layer ILD1 and the contact hole of the gate insulating layer GI such as to form a through-hole or a single contact hole.

The first connection electrode CNE1 may be disposed on the second interlayer insulating layer ILD2. The first connection electrode CNE1 may electrically connect the drain electrode DE of the thin film transistor TFT and the second connection electrode CNE2 to each other. The first connection electrode CNE1 may be inserted into (or extended completely through) the contact holes formed in the second interlayer insulating layer ILD2, the first interlayer insulating layer ILD1, and the gate insulating layer GI to be in contact with the drain electrode DE of the thin film transistor TFT. As being in contact, elements may form a (physical) interface therebetween.

The first passivation layer PAS1 may cover the first connection electrode CNE1 and the second interlayer insulating layer ILD2. The first passivation layer PAS1 may protect the thin film transistor TFT. The first passivation layer PAS1 may include a contact hole through which the second connection electrode CNE2 penetrates the first passivation layer PAS1.

The second connection electrode CNE2 may be disposed on the first passivation layer PAS1. The second connection electrode CNE2 may electrically connect the first connection electrode CNE1 and a pixel electrode AE of a light emitting element ED to each other. The second connection electrode CNE2 may be inserted into the contact hole formed in the first passivation layer PAS1 and be in contact with the first connection electrode CNE1.

The second passivation layer PAS2 may cover the second connection electrode CNE2 and the first passivation layer PAS1. The second passivation layer PAS2 may include a contact hole through which the pixel electrode AE of the light emitting element ED penetrates the second passivation layer PAS2.

A light emitting element layer EML may be disposed on the thin film transistor layer TFTL. The light emitting element layer EML may include a light emitting element ED and a pixel defining film PDL. The light emitting element ED may include a pixel electrode AE, a light emitting layer EL, and a common electrode CO.

The pixel electrode AE may be disposed on the second passivation layer PAS2. The pixel electrode AE may be disposed to overlap any one of openings OPE1, OPE2, and OPE3 as pixel openings of the pixel defining film PDL. The pixel electrode AE may be electrically connected to the drain electrode DE of the thin film transistor TFT through the first and second connection electrodes CNE1 and CNE2. The pixel electrode AE may include an exposed portion which is exposed to outside a solid portion of the pixel defining film PDL at the respective pixel openings therein.

The light emitting layer EL may be disposed on the pixel electrode AE. For example, the light emitting layer EL may be an organic light emitting layer made of an organic material, but is not limited thereto. In the case in which the light emitting layer EL corresponds to the organic light emitting layer, when the thin film transistor TFT applies a predetermined voltage to the pixel electrode AE of the light emitting element ED and the common electrode CO of the light emitting element ED receives a common voltage or a cathode voltage, each of the holes and electrons may move to the light emitting layer EL through the hole transporting layer and the electron transporting layer, and the holes and electrons may be bonded to each other in the light emitting layer EL to emit light.

The common electrode CO may be disposed on the light emitting layer EL. For example, the common electrode CO may be implemented in the form of an electrode common to all pixels without being divided for each of the plurality of pixels. The common electrode CO may be disposed on the light emitting layer EL in the first to third light emitting areas EA1, EA2, and EA3, and may be disposed on the pixel defining film PDL in an area excluding the first to third light emitting areas EA1, EA2, and EA3.

The common electrode CO may receive a common voltage or a low potential voltage. In the case in which the pixel electrode AE receives a voltage corresponding to the data voltage and the common electrode CO receives the low potential voltage, as a potential difference is formed (or provided) between the pixel electrode AE and the common electrode CO, the light emitting layer EL may emit light.

The pixel defining film PDL may include (or define) a plurality of openings OPE1, OPE2, and OPE3, and may be disposed on the second passivation layer PAS2 and a portion of the pixel electrode AE. The solid portion of the pixel defining film PDL and the pixel openings defined thereby may together form a pixel defining layer. The pixel defining film PDL may include a first opening OPE1, a second opening OPE2, and a third opening OPE3, and each of the openings OPE1, OPE2, and OPE3 may expose a portion of the pixel electrode AE to outside the pixel defining layer. As described above, each of the openings OPE1, OPE2, and OPE3 of the pixel defining film PDL may define the first to third light emitting areas EA1, EA2, and EA3, and the first to third light emitting areas EA1, EA2, and EA3 may have different areas or sizes. The pixel defining film PDL may separate and insulate the pixel electrodes AE of the plurality of light emitting elements ED from each other.

The pixel defining film PDL may include a light absorbing material to prevent light reflection. For example, the pixel defining film PDL may include a polyimide (PI)-based binder, and a pigment in which red, green, and blue colors are combined. Alternatively, the pixel defining film PDL may include a cardo-based binder resin, and a combination of lactam black pigment and blue pigment. Alternatively, the pixel defining film PDL may include carbon black.

A spacer SPC may be disposed on the pixel defining film PDL. The spacer SPC may function to prevent lower layers from being damaged by being in contact with a mask during a process of depositing the light emitting layer EL. The spacer SPC may be disposed directly on the pixel defining film PDL and may be disposed to overlap the non-light emitting area NEA. The spacer SPC may include an organic material and be formed to have a thickness of about 1 micrometer (μm) or more.

Meanwhile, the light emitting element layer EML may include an uneven portion UEP. The uneven portion UEP includes a plurality of protrusions PRJ and may include a depression which is disposed between the plurality of protrusions PRJ. The uneven portion UEP may be disposed between the pixel defining film PDL and the common electrode CO, and may be directly disposed in contact with an upper surface of the pixel defining film PDL. The uneven portion UEP may be disposed to overlap the non-light emitting area NEA, and may be disposed to non-overlap the first to third light emitting areas EA1, EA2, and EA3 or the first to third openings OPE1, OPE2, and OPE3. A portion of the uneven portion UEP may be disposed to overlap the first to third light exit portions OPT1, OPT2, and OPT3.

The uneven portion UEP may include a plurality of protrusions PRJ which protrude from a surface of the pixel defining film PDL in the third direction DR3. The plurality of protrusions PRJ may have a shape whose area gradually decreases in a direction from the surface of the pixel defining film PDL toward the color filter layer CFL. A width of the protrusions PRJ shown in FIG. 10 represents the decreasing planar area of the protrusions PRJ along the thickness direction. In an embodiment, for example, each of the protrusions PRJ has a planar area in a plan view, and the planar area decreases in a direction from the pixel defining film PDL to the reflection control layer.

Within the plurality of protrusions PRJ, even when a material is the same and a refractive index is constant, the refractive index decreases as the size (or area) decreases, and the refractive index is recognized as gradually decreasing. For example, light LEL (refer to FIG. 11) incident on the upper surface of the plurality of protrusions PRJ is recognized as having a gradually decreasing refractive index as it transmits through the plurality of protrusions PRJ, and thus Fresnel reflection does not occur. Accordingly, the light LEL incident on the plurality of protrusions PRJ is transmitted as is without being reflected. In an embodiment, the uneven portion UEP including the plurality of protrusions PRJ may have a moth eye fine structure.

The shape of the plurality of protrusions PRJ is not particularly limited as long as the area gradually decreases from the surface of the pixel defining film PDL toward the color filter layer CFL. For example, the plurality of protrusions PRJ may have a hexahedral shape as illustrated in FIG. 10 (e.g., four side surfaces, a top surface closest to the color filter layer CFL and a bottom surface furthest from the color filter layer CFL), but is not limited thereto and may have a hemispherical shape, a cone shape, a polygonal pyramid shape, etc.

The plurality of protrusions PRJ may be disposed at a pitch P of about 0.5 μm to about 2 micrometers (μm) to suppress reflection of visible light. When the pitch P of the plurality of protrusions PRJ is within the above-mentioned range, a difference in color between reflected light may be reduced and reflection of external light may be prevented. The plurality of protrusions PRJ may have a width W of about 0.5 μm to about 2 μm. When the width W of the plurality of protrusions PRJ is within the above-mentioned range, a difference in color between reflected light may be reduced and reflection of external light may be prevented. While the pitch P and the width W are shown in FIG. 12 along the first direction DR1, it will be understood that these characteristics may also be defined along another planar direction like the second direction DR2.

In addition, the plurality of protrusions PRJ may have a thickness of about 0.5 μm to about 1 μm. When the thickness of the plurality of protrusions PRJ is within the above-mentioned range, a difference in color of reflected light may be prevented from increasing. A thickness of the protrusions PRJ may also be referred to as a height defined along the thickness direction.

In some embodiments, the thickness of the plurality of protrusions PRJ may be smaller than a thickness of the spacer SPC by about 1 μm or more. When the thickness of the plurality of protrusions PRJ is smaller than the thickness of the spacer SPC by about 1 μm or more, it is possible to prevent the protrusions PRJ from being damaged by a mask during the process of depositing a material for forming the light emitting layer EL. In an embodiment, for example, the spacer SPC is coplanar with the layer of protrusions PRJ and has a thickness along a thickness direction of the display device 10. Here, a thickness of each protrusion PRJ is smaller than the thickness of the spacer SPC.

The first to third light exit portions OPT1, OPT2, and OPT3 may be areas where light emitted from the light emitting element ED and light incident from the outside are emitted and reflected, respectively, from the display device 10. In overlapping areas where the first to third light exit portions OPT1, OPT2, and OPT3 each overlap the non-light emitting area NEA, the light incident from the outside may be reflected by the common electrode CO. The reflected light reflected by the common electrode CO may interfere with other reflected light and may display a specific color while passing through the color filters CF1, CF2, and CF3. Accordingly, a black color of the display device 10 may be distorted. In the present embodiment, by disposing the plurality of protrusions PRJ between the light blocking pattern BM, which will be described later, and the first to third light emitting areas EA1, EA2, and EA3, the reflection of light incident from the outside may be reduced and the black color may be improved.

Meanwhile, the uneven portion UEP may be disposed to further extend on an inclined surface PDC of the pixel defining film PDL.

Referring to FIG. 13, the pixel defining film PDL may include an inclined surface PDC which defines the pixel opening. The inclined surface PDC of the pixel defining film PDL may be an area of the pixel defining layer from a portion (or edge) where the pixel electrode AE and the pixel defining film PDL meet and a portion (or edge) parallel to the upper surface of the second passivation layer PAS2. The inclined surface PDC of the pixel defining film PDL may not overlap the first to third light emitting areas EA1, EA2, and EA3, and may overlap the non-light emitting area NEA and the first to third light exit portions OPT1, OPT2, and OPT3. A lower boundary of the inclined surface PDC may define an area of the respective light emitting area.

As a taper angle of the inclined surface PDC of the pixel defining film PDL decreases, the area of the inclined surface PDC increases, which may result in more reflection of external light at the respective light emitting area. In the present embodiment, by disposing the plurality of protrusions PRJ of the uneven portion UEP on the inclined surface PDC of the pixel defining film PDL, the reflection of external light may be further reduced.

In an embodiment, the uneven portion UEP may be extended to and disposed in an area overlapping the non-light emitting area NEA and the first to third exit portions OPT1, OPT2, and OPT3.

Referring to FIGS. 14 and 15, the uneven portion UEP may be disposed to non-overlap the first to third light emitting areas EA1, EA2, and EA3, and overlap an overlapping area of the non-light emitting area NEA and the first to third light exit portions OPT1, OPT2, and OPT3. For example, the plurality of protrusions PRJ may be disposed to non-overlap the light blocking pattern BM in the non-light emitting area NEA. That is, the display device 10 may include an overlapping area defined where the light exit opening of the light blocking layer (BM+OPT) and the non-light emitting area overlap each other, and the uneven portion UEP is in the overlapping area and non-overlapping the light blocking pattern BM.

An overlapping area of the non-light emitting area NEA which overlaps the first to third light exit portions OPT1, OPT2, and OPT3 may be vulnerable to the reflection of external light. For example, the area of the non-light emitting area NEA which overlaps the light blocking pattern BM may block or absorb external light or reflected light by the light blocking pattern BM. An area of the non-light emitting area NEA which does not overlap the light blocking pattern BM may be vulnerable to the reflection of external light because the reflected light is emitted upward.

In the present embodiment, by disposing the uneven portion UEP in the area of the non-light emitting area NEA which does not overlap the light blocking pattern BM or in the overlapping area where the non-light emitting area NEA overlaps the first to third light exit portions OPT1, OPT2, and OPT3, the reflection of light incident from the outside may be reduced and the black color may be further improved.

The plurality of protrusions PRJ described above may be manufactured (or provided) in a separate process from the spacer SPC or may be manufactured together with the spacer SPC. For example, the spacer SPC and the plurality of protrusions PRJ may be simultaneously patterned and manufactured using a halftone mask after coating an organic material. That is, the spacer SPC and the protrusions PRJ may be in a same layer as each other, as being respective patterns of a same material layer.

In an embodiment, the plurality of protrusions PRJ may be formed integrally with the pixel defining film PDL.

Referring to FIGS. 16 and 17, the pixel defining film PDL may include extended portions which define the layer of protrusions PRJ. The plurality of protrusions PRJ may be formed integrally with the pixel defining film PDL. That is, the protrusions PRJ and the pixel defining film PDL may be a single, unitary body. For example, the plurality of protrusions PRJ may be formed simultaneously using a halftone mask after coating an organic material for forming the pixel defining film PDL.

The present embodiment has an advantage of omitting a separate process for forming the plurality of protrusions PRJ.

Meanwhile, referring again to FIG. 10, the encapsulation layer TFEL may be disposed on the common electrode CO to cover the plurality of light emitting elements ED. The encapsulation layer TFEL may include at least one inorganic film to prevent oxygen or moisture from permeating into the light emitting element layer EML. The encapsulation layer TFEL may include at least one organic film to protect the light emitting element layer EML from foreign substances such as dust.

The encapsulation layer TFEL may include a first encapsulation layer TFE1, a second encapsulation layer TFE2, and a third encapsulation layer TFE3. The first encapsulation layer TFEL and the third encapsulation layer TFE3 may be inorganic encapsulation layers, and the second encapsulation layer TFE2 disposed therebetween may be an organic encapsulation layer.

Each of the first encapsulation layer TFE1 and the third encapsulation layer TFE3 may include one or more inorganic insulating materials. The inorganic insulating material may include aluminum oxide, titanium oxide, tantalum oxide, hafnium oxide, zinc oxide, silicon oxide, silicon nitride, and/or silicon oxynitride.

The second encapsulation layer TFE2 may include an organic insulating material. The organic insulating material may include, for example, acrylic resin, epoxy resin, polyimide, and polyethylene. The second encapsulation layer TFE2 may be formed by curing a monomer or applying a polymer.

The touch sensing layer TSU may be disposed on the encapsulation layer TFEL. The touch sensing layer TSU may include a touch insulating layer TNS, a driving electrode TE, and a bridge electrode CE. Although not illustrated, the touch sensing layer TSU may further include the sensing electrode RE illustrated in FIG. 7.

The driving electrode TE may be disposed on the third encapsulation layer TFE3. The driving electrode TE may be formed as a single layer (e.g., a monolayer) made of molybdenum (Mo), titanium (Ti), copper (Cu), aluminum (Al), or indium tin oxide (ITO), or be formed as a stacked structure (Ti/Al/Ti) of aluminum and titanium, a stacked structure (ITO/AI/ITO) of aluminum and ITO, an APC alloy, and a stacked structure (ITO/APC/ITO) of an APC alloy and ITO. The driving electrode TE may be disposed to non-overlap the first to third light emitting areas EA1, EA2, and EA3.

The touch insulating layer TNS may be disposed on the driving electrode TE and the third encapsulation layer TFE3. The touch insulating layer TNS may include an organic film or an inorganic film. For example, the touch insulating layer TNS may include an organic film such as acrylic resin, epoxy resin, polyimide, or polyethylene, or may include an inorganic film such as silicon nitride, silicon oxide, or silicon nitride.

The bridge electrode CE may be disposed on the touch insulating layer TNS and may be connected to the driving electrode TE through a contact hole penetrating through the touch insulating layer TNS. The bridge electrode CE may be made of the materials exemplified in the driving electrode TE.

The driving electrode TE and the bridge electrode CE of the touch sensing layer TSU may be disposed to overlap the plurality of protrusions PRJ and the light blocking pattern BM. Therefore, the driving electrode TE and the bridge electrode CE may be prevented from being visually recognized from the outside by being covered by the light blocking pattern BM.

A color filter layer CFL may be disposed on the touch sensing layer TSU. The color filter layer CFL may be a reflection control layer which controls reflection of external light. The color filter layer CFL may include a plurality of color filters CF1, CF2, and CF3 and a light blocking pattern BM. Each of the color filters may selectively transmit light of a specific wavelength and block or absorb light of a different wavelength. The color filter layer CFL may absorb a portion of light introduced from the outside of the display device 10 to reduce reflected light caused by external light. Therefore, the color filter layer CFL may prevent color distortion caused by reflection of external light.

The light blocking pattern BM may be disposed on the touch insulating layer TNS of the touch sensing layer TSU. The light blocking pattern BM may be disposed to cover a conductive line of the driving electrode TE, and may partition the plurality of light exit portions OPT1, OPT2, and OPT3 disposed to overlap the first to third light emitting areas EA1, EA2, and EA3. For example, the first light exit portion OPT1 may be disposed to overlap the first light emitting area EA1 or the first opening OPE1. The second light exit portion OPT2 may be disposed to overlap the second light emitting area EA2 or the second opening OPE2, and the third light exit portion OPT3 may be disposed to overlap the third light emitting area EA3 or the third opening OPE3. Although not illustrated in the drawing, the fourth light exit portion OPT4 may be disposed to overlap the fourth light emitting area EA4 or the fourth opening OPE4.

The area or size of each of the light exit portions OPT1, OPT2, OPT3, and OPT4 may be greater than the area or size of the openings OPE1, OPE2, OPE3, and OPE4 of the pixel defining film PDL. That is, along the thickness direction, a light emitting opening may be widest (or largest) at the light exit portion and narrowest (or smallest) at the light emitting area. As the light exit portions OPT1, OPT2, OPT3, and OPT4 of the light blocking pattern BM are formed to be greater than the openings OPE1, OPE2, OPE3, and OPE4 of the pixel defining film PDL, light emitted from the light emitting areas EA1, EA2, EA3, and EA4 may be visually recognized from outside the electronic device 1 such as by a user not only from a front side of the display device 10 but also from a side thereof.

The light blocking pattern BM may include a light absorbing material. For example, the light blocking pattern BM may include an inorganic black pigment or an organic black pigment. The inorganic black pigment may be carbon black, and the organic black pigment may include at least one of lactam black, perylene black, and aniline black, but is not limited thereto. The light blocking pattern BM may prevent visible light from permeating and combining colors between the first to fourth light emitting areas EA1, EA2, EA3, and EA4, thereby improving a color reproduction rate of the display device 10.

In an embodiment, the light blocking pattern BM may be defined as an area where the plurality of color filters CF1, CF2, and CF3 overlap each other. For example, an area where a first color filter CF1, a second color filter CF2, and a third color filter CF3, which will be described later, overlap each other in the third direction DR3 may be defined as the light blocking pattern BM (e.g., a light blocking area). In this case, the first color filter CF1, the second color filter CF2, and the third color filter CF3 may block the remaining light except for red, green, and blue light, respectively, thereby ultimately blocking light.

The plurality of color filters CF1, CF2, and CF3 of the color filter layer CFL may be disposed on the light blocking pattern BM and the touch insulating layer TNS. The plurality of color filters CF1, CF2, and CF3 may include a first color filter CF1, a second color filter CF2, and a third color filter CF3.

The first color filter CF1 may be disposed to overlap the first light exit portion OPT1 and the first light emitting area EA1, and a portion of the first color filter CF1 may be disposed to overlap the non-light emitting area NEA. The first color filter CF1 may selectively transmit the light of the first color (e.g., red light) and may block or absorb the light of the second color (e.g., blue light) and the light of the third color (e.g., green light). For example, the first color filter CF1 may be a red color filter and include a red colorant, but is not limited thereto.

The second color filter CF2 may be disposed to overlap the second light exit portion OPT2 and the second light emitting area EA2, and a portion of the second color filter CF2 may be disposed to overlap the non-light emitting area NEA. The second color filter CF2 may selectively transmit the light of the second color (e.g., blue light) and may block or absorb the light of the third color (e.g., green light) and the light of the first color (e.g., red light). For example, the second color filter CF2 may be a blue color filter and include a blue colorant, but is not limited thereto.

The third color filter CF3 may be disposed to overlap the third light exit portion OPT3 and the third light emitting area EA3, and a portion of the third color filter CF3 may be disposed to overlap the non-light emitting area NEA. The third color filter CF3 may selectively transmit the light of the third color (e.g., green light) and may block or absorb the light of the first color (e.g., red light) and the light of the second color (e.g., blue light). For example, the third color filter CF3 may be a green color filter and include a green colorant, but is not limited thereto. Although not illustrated, the fourth color filter CF4 may be a green color filter like the third color filter CF3, and may be disposed to overlap the fourth light exit portion OPT4 and the fourth light emitting area EA4.

The overcoat layer OC may be disposed on the color filter layer CFL. The overcoat layer OC may cover the color filter layer CFL to planarize a lower level difference. The overcoat layer OC may be a colorless light-transmitting layer having no color in a visible light band. For example, the overcoat layer OC may include a colorless light-transmitting organic material such as an acrylic resin or polyimide.

In some embodiments, the overcoat layer OC may further include a dye capable of selectively absorbing light in a specific wavelength band. The overcoat layer OC may reduce a reflectance of external light by absorbing light in a partial wavelength band of light incident from the outside.

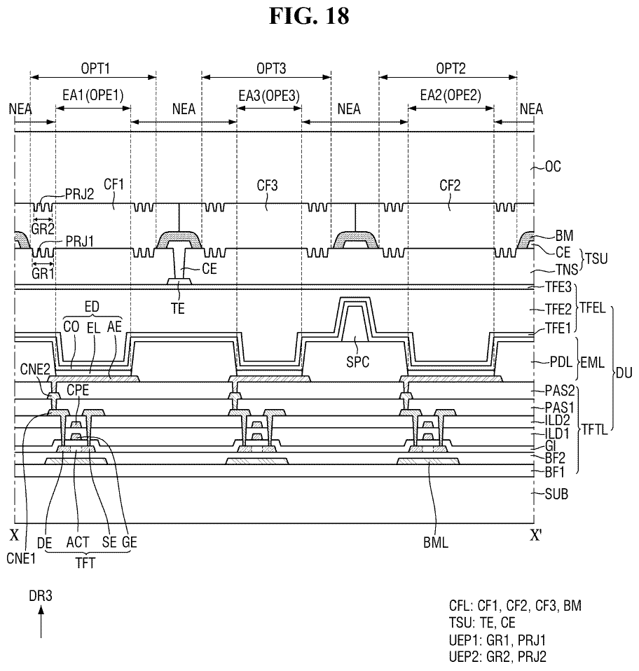

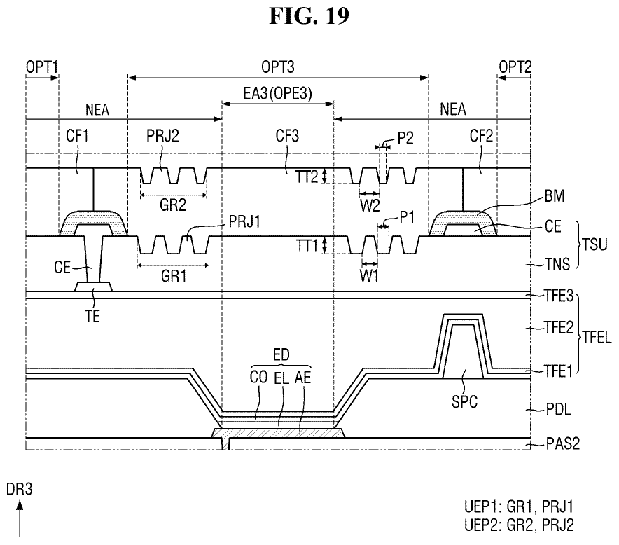

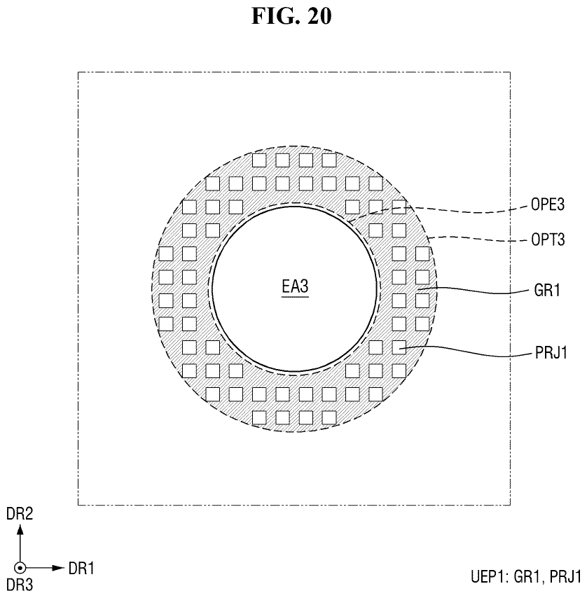

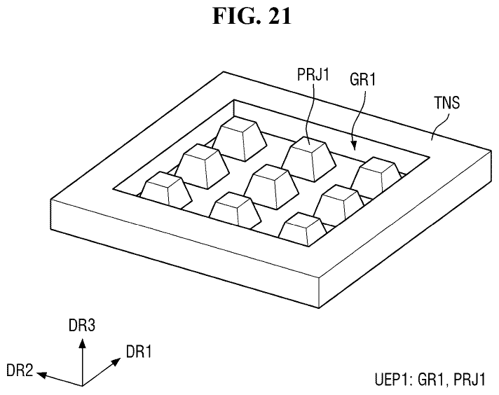

FIG. 18 is a cross-sectional view schematically illustrating a display device 10 according to an embodiment. FIG. 19 is an enlarged cross-sectional view illustrating a peripheral area of a third light emitting area EA3 of a display device 10 according to an embodiment. FIG. 20 is an enlarged plan view illustrating the peripheral area of the third light emitting area EA3 of FIG. 19. FIG. 21 is a perspective view schematically illustrating a first groove GR1 and first protrusions PRJ1 of a touch insulating layer TNS.

Referring to FIGS. 18 to 21, the present embodiment is different from the embodiments of FIGS. 10 to 17 in that the touch sensing layer TSU includes a first uneven portion UEP1 and the color filter layer CFL includes a second uneven portion UEP2. Hereinafter, descriptions overlapping the above-described embodiment will be omitted and differences from the above-described embodiment will be described.

The display panel 100 of the display device 10 according to an embodiment may include a display layer DU, a touch sensing layer TSU, a color filter layer CFL, and an overcoat layer OC.

The touch sensing layer TSU may include a first groove GR1 and a plurality of first protrusions PRJ1 disposed in the first groove GR1, to define a first uneven portion UEP1. A sub-groove may be defined between first protrusions PRJ1 adjacent to each other along the first groove GR1.

The first uneven portion UEP1 may be disposed on the touch insulating layer TNS. For example, the first groove GR1 of the first uneven portion UEP1 may be formed concavely from an upper surface of the touch insulating layer TNS toward the substrate SUB. The first uneven portion UEP1 may be disposed to overlap the non-light emitting area NEA between the light blocking pattern BM and a respective light emitting area, and the first groove GR1 and the plurality of protrusions PRJ1 may also overlap the non-light emitting area NEA. The first uneven portion UEP1 may be disposed to non-overlap the first to third light emitting areas EA1, EA2, and EA3 or the first to third openings OPE1, OPE2, and OPE3. In addition, the first uneven portion UEP1 may be disposed to overlap the first to third light exit portions OPT1, OPT2, and OPT3. The first uneven portion UEP1 may be disposed to each surround the first to third light emitting areas EA1, EA2, and EA3 in plan view.

A width of the first uneven portion UEP1 may be smaller than or equal to a width of an overlapping area where the first to third light exit portions OPT1, OPT2, and OPT3 overlap the non-light emitting area NEA. However, the first uneven portion UEP1 is not limited thereto, and may also overlap the light blocking pattern BM so long as it does not overlap the first to third light emitting areas EA1, EA2, and EA3.

The plurality of first protrusions PRJ1 of the first uneven portion UEP1 may be disposed in a same one of the first groove GR1, and may define a fine uneven shape protruding from a bottom surface of the first groove GR1 in the third direction DR3. The plurality of first protrusions PRJ1 may include the same material as the touch insulating layer TNS and may be formed integrally therewith. When external light is incident on the plurality of first protrusions PRJ1 in the same manner as in the above-described embodiment, a refractive index is recognized as gradually decreasing due to fine irregularities, and thus Fresnel reflection does not occur. Accordingly, the light incident on the plurality of first protrusions PRJ1 is transmitted as is without being reflected. In an embodiment, the first uneven portion UEP1 may have a moth eye fine structure.

The plurality of first protrusions PRJ1 may be disposed to overlap the non-light emitting area NEA between the light blocking pattern BM and a respective light emitting area, and may be disposed to non-overlap the first to third light emitting areas EA1, EA2, and EA3 or the first to third openings OPE1, OPE2, and OPE3. In addition, the plurality of first protrusions PRJ1 may be disposed to overlap the first to third light exit portions OPT1, OPT2, and OPT3.

The plurality of first protrusions PRJ1 may have a pitch P1 of about 0.5 μm to about 2 μm, and a width W1 of about 0.5 μm to 2 μm. In addition, the plurality of first protrusions PRJ1 may have a height TT1 of about 0.5 μm to about 1 μm. A smaller thickness portion of the touch insulating layer TNS may remain at the sub-grooves such that a plurality of recesses are defined for the first groove GR1. The bottom surface of the first groove GR1 may be defined by such thickness portion. When the pitch P1, width W1, and height TT1 of the plurality of first protrusions PRJ1 are within the above-mentioned ranges, a difference in color of reflected light may be reduced, reflection of external light may be prevented, and a second groove GR2 and a second protrusion PRJ2, which will be described later, may be easily formed.

As described above, in the area of the first to third light exit portions OPT1, OPT2, and OPT3 which overlaps the non-light emitting area NEA, the light incident from the outside may be reflected by the common electrode CO. In the present embodiment, by disposing the first groove GR1 and the first uneven portion UEP1 including the plurality of first protrusions PRJ1 which are disposed in the first groove GR1 on the touch insulating layer TNS between the light blocking pattern BM and the first to third light emitting areas EA1, EA2, and EA3, the reflection of light incident from the outside may be reduced.

Meanwhile, the plurality of color filters CF1, CF2, and CF3 disposed on the touch insulating layer TNS may include a second groove GR2 and a plurality of second protrusions PRJ2 which are disposed in the second groove GR2 to define a second uneven portion UEP2. A sub-groove may be defined between second protrusions PRJ2 adjacent to each other along the second groove GR2.

The second uneven portion UEP2 may be disposed in each color filter CF1, CF2, and CF3. For example, the second groove GR2 may be formed concavely from an upper surface of each color filter CF1, CF2, and CF3 toward the substrate SUB. The second uneven portion UEP2 and the second groove GR2 may be disposed to overlap the non-light emitting area NEA between the light blocking pattern BM and a respective light emitting area, and may be disposed to non-overlap the first to third light emitting areas EA1, EA2, and EA3 or the first to third openings OPE1, OPE2, and OPE3. In addition, the second uneven portion UEP2 may be disposed to overlap the first to third light exit portions OPT1, OPT2, and OPT3. The second uneven portion UEP2 may be disposed to each surround the first to third light emitting areas EA1, EA2, and EA3 in plan view.

A total width of the second uneven portion UEP2 may be a total width of the second groove GR2. The width of the second uneven portion UEP2 and the width of the second groove GR2 may be smaller than a width of an area where the first to third light exit portions OPT1, OPT2, and OPT3 overlap the non-light emitting area NEA. The total width of the second uneven portion UEP2 may be smaller than the total width of the first uneven portion UEP1. For example, the total width of the second groove GR2 may be smaller than the total width of the first groove GR1.

A cross-sectional profile of the second uneven portion UEP2 may be formed by a level difference of the cross-sectional profile of the first uneven portion UEP1 when applying a material for forming each color filter CF1, CF2, and CF3 on the first uneven portion UEP1 which is in the touch insulating layer TNS. Therefore, the total width of the second uneven portion UEP2 may be formed to be smaller than the total width of the first uneven portion UEP1, and a total area (e.g., planar area) of the second uneven portion UEP2 may also be formed to be smaller than a total area of the first uneven portion UEP1. For example, an area of the second groove GR2 may be formed to be smaller than an area of the first groove GR1. In addition, along the thickness direction, a depth of the second groove GR2 may be formed to be smaller than a depth of the first groove GR1.

The plurality of second protrusions PRJ2 of the second uneven portion UEP2 may be disposed in the second groove GR2, and may have a fine uneven shape protruding from a bottom surface of the second groove GR2 in the third direction DR3. A smaller thickness portion of a respective color filter may remain at the sub-grooves such that a plurality of recesses are defined for the second groove GR2. The bottom surface of the second groove GR2 may be defined by such thickness portion. The second uneven portion UEP2 may be formed integrally with each color filter CF1, CF2, and CF3. When external light is incident on the plurality of second protrusions PRJ2 in the same manner as in the above-described embodiment, a refractive index is recognized as gradually decreasing due to fine irregularities, and thus Fresnel reflection does not occur. Accordingly, the light incident on the plurality of second protrusions PRJ2 is transmitted as is without being reflected. In an embodiment, the second uneven portion UEP2 may have a moth eye fine structure.

The plurality of second protrusions PRJ2 may be disposed to overlap the non-light emitting area NEA, and may be disposed to non-overlap the first to third light emitting areas EA1, EA2, and EA3 or the first to third openings OPE1, OPE2, and OPE3. In addition, the plurality of second protrusions PRJ2 may be disposed to overlap the first to third light exit portions OPT1, OPT2, and OPT3.

The plurality of second protrusions PRJ2 may be disposed to overlap the plurality of first protrusions PRJ1. The plurality of second protrusion PRJ2 may be formed by a level difference of the first protrusion PRJ1 when applying color filter material for forming each color filter CF1, CF2, and CF3 on the plurality of first protrusions PRJ1 which is in the touch insulating layer TNS. Therefore, the plurality of second protrusions PRJ2 may be disposed to overlap the plurality of first protrusions PRJ1.

The plurality of second protrusions PRJ2 may have a pitch P2 of about 0.5 μm to about 2 μm, and a width W2 of about 0.5 μm to about 2 μm. In addition, the plurality of second protrusions PRJ2 may have a height TT2 of about 0.5 μm to about 1 μm. When the pitch P2, width W2, and height TT2 of the plurality of second protrusions PRJ2 are within the above-mentioned ranges, a difference in color of reflected light may be reduced and reflection of external light may be prevented.

In addition, the pitch P2 of the plurality of second protrusions PRJ2 may be smaller than the pitch P1 of the plurality of first protrusions PRJ1, the width W2 of the second protrusion PRJ2 may be greater than the width W1 of the plurality of first protrusions PRJ1, and the height TT2 of the second protrusion PRJ2 may be smaller than the height TT1 of the plurality of first protrusions PRJ1.

In the present embodiment, by disposing the first groove GR1 and the first uneven portion UEP1 including the plurality of first protrusions PRJ1 in each color filter CF1, CF2, and CF3 at the same time as disposing the second groove GR2 and the second uneven portion UEP2 including the plurality of second protrusions PRJ2 in each color filter CF1, CF2, and CF3 at respective locations between the light blocking pattern BM and the first to third light emitting areas EA1, EA2, and EA3, the reflection of light incident from the outside may be further reduced.

In one or more embodiment described above, a display device 10 includes a pixel defining film PDL which partitions a light emitting area and a non-light emitting area NEA adjacent to each other within the display area DA, a pixel electrode AE in the light emitting area and overlapped by the pixel defining film PDL, a light emitting layer EL on the pixel electrode AE, a common electrode CO on the pixel defining film PDL and the light emitting layer EL, an encapsulation layer TFEL on the common electrode CO, a reflection control layer on the encapsulation layer TFEL, and an uneven portion UEP defined by a layer of protrusions PRJ between the pixel defining film PDL and the reflection control layer, the protrusions PRJ overlapping the non-light emitting area NEA and non-overlapping the light emitting area.

Meanwhile, in the display device 10 according to the above-described embodiments, a polarizing member POL may also be applied as the reflection control layer instead of the color filter layer CFL.

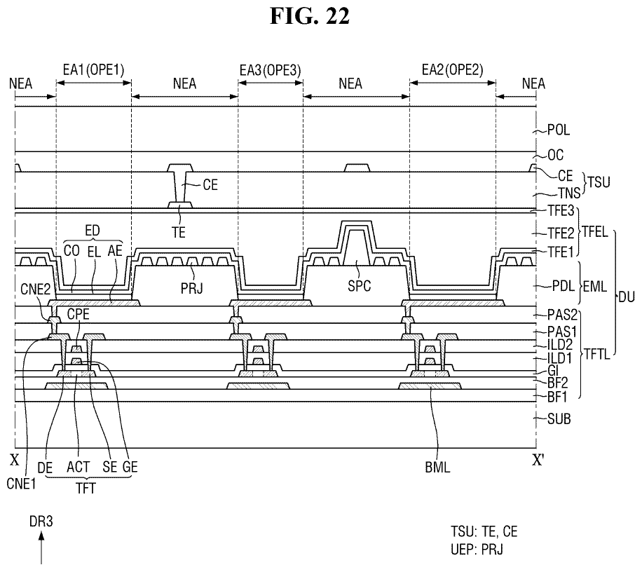

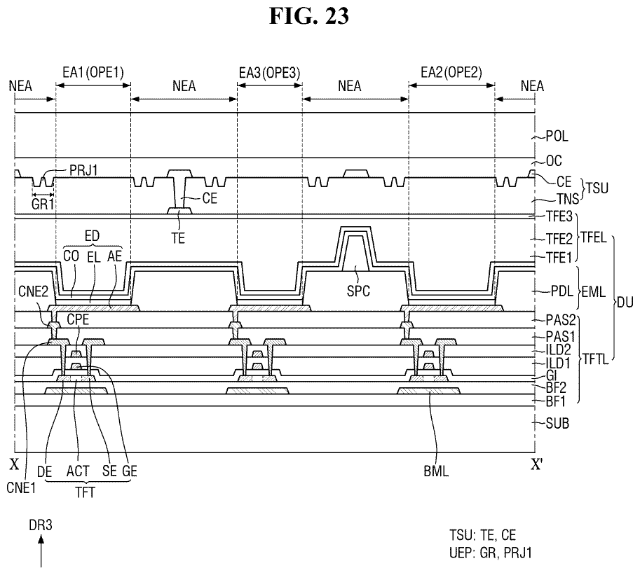

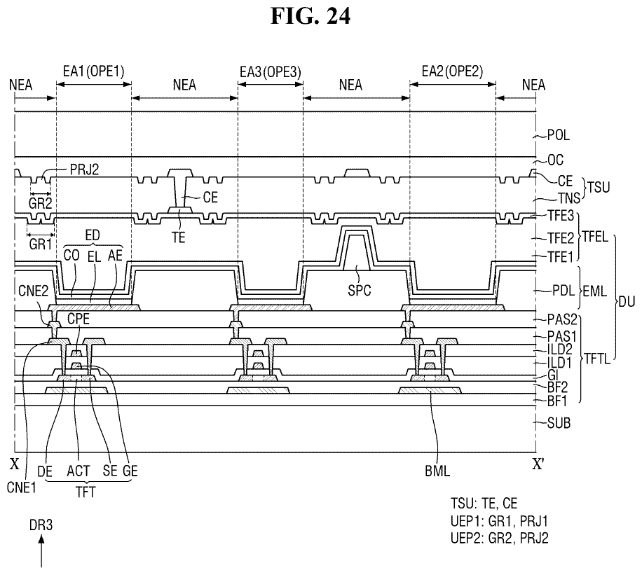

FIG. 22 is a cross-sectional view schematically illustrating a display device 10 according to an embodiment. FIG. 23 is a cross-sectional view schematically illustrating a display device 10 according to an embodiment. FIG. 24 is a cross-sectional view schematically illustrating a display device 10 according to an embodiment.

FIG. 22 illustrates an example in which the color filter layer CFL is omitted from FIG. 10 and a polarizing member POL is disposed, and FIG. 23 illustrates an example in which the color filter layer CFL is omitted from FIG. 18 and a polarizing member POL is disposed. In addition, FIG. 24 illustrates an example in which the first uneven portion UEP1 is disposed on the second encapsulation layer TFE2 and the second uneven portion UEP2 is disposed on the touch insulating layer TNS in FIG. 23.

Referring to FIGS. 22 and 23, an overcoat layer OC may be disposed on the touch sensing layer TSU, and a polarizing member POL may be disposed on the overcoat layer OC. The overcoat layer OC may planarize a level difference of the touch sensing layer TSU so that the polarizing member POL may be well attached. The polarizing member POL may function as a reflection control layer which prevents reflection of external light by converting a polarization axis of light incident from the outside and blocking transmission of light reflected and emitted from the display layer DU.

In the embodiment of FIG. 22, an uneven portion UEP including a plurality of protrusions PRJ may be disposed in the non-light emitting area NEA on the pixel defining film PDL, and in the embodiment of FIG. 23, a first uneven portion UEP1 including a first groove GR1 and a plurality of first protrusions PRJ1 disposed in the first groove GR1 may be disposed in the non-light emitting area NEA of the touch insulating layer TNS. In addition, in the embodiment of FIG. 24, a first uneven portion UEP1 including a first groove GR1 and a plurality of first protrusions PRJ1 disposed in the first groove GR1 may be disposed in the non-light emitting area NEA on the second encapsulation layer TFE2, and a second uneven portion UEP2 including a second groove GR2 and a plurality of second protrusions PRJ2 disposed in the second groove GR2 may be disposed in the non-light emitting area NEA of the touch insulating layer TNS. Accordingly, it is possible to reduce a reflection of light incident from the outside by a fine structure of the uneven portion UEP in the non-light emitting area NEA.

Hereinafter, the display device 10 of the present disclosure will be described in detail in the following manufacturing examples and experimental examples. However, the following manufacturing examples and experimental examples are merely illustrative of the present disclosure and the present disclosure is not limited to the following examples.

### <First Manufacturing Example: Manufacturing of Display Panel>

Display panel samples illustrated in FIG. 10 were manufactured. Each sample was manufactured with the same structure except that the width and spacing of a mask pattern for manufacturing a plurality of protrusions were changed as illustrated in Table 1 below. In this case, the exposure time was all performed the same at 1250 milliseconds (ms). In addition, in Table 1 below, whether the protrusions are formed was indicated by O if it is confirmed that the protrusions are normally formed in the entire area of the pixel defining film, and was indicated by X if it is confirmed that the protrusions are partially formed or are not formed.

TABLE 1

| | | | Whether |
|---|---|---|---|
| | | Patten Spacing | Protrusions Are |
| | Patten Width (μm) | (μm) | Formed |
| Sample 1 | 1.2 | 1.2 | X |
| Sample 2 | 1.4 | 1.4 | X |
| Sample 3 | 1.6 | 1.6 | ο |
| Sample 4 | 1.8 | 1.8 | X |

### <First Experimental Example: Reflectance Measurement>

The reflectance and reflection color of black of display panel samples 1 to 4 were measured. The reflectance and reflection color were measured using a spectrophotometer, and the reflectance was measured using the Specular Component Excluded (SCE) method, which measures reflected light with regular reflected light removed, and the Specular Component Included (SCI) method, which measures reflected light including regular reflected light.

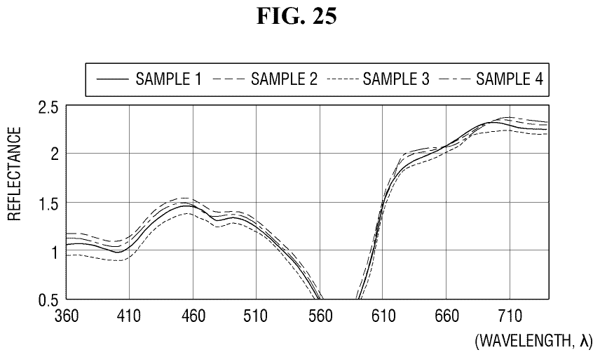

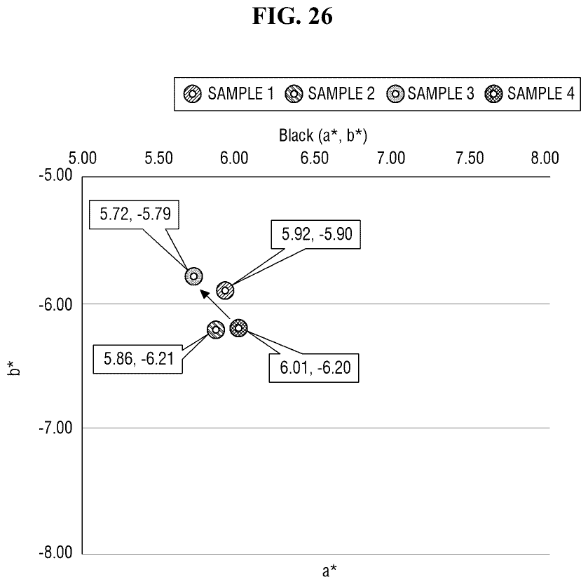

FIG. 25 is a graph illustrating an SCE reflectance according to a wavelength (2) band of display panel samples 1 to 4 according to a first experimental example. FIG. 26 is a graph illustrating a reflection color of black of display panel samples 1 to 4 according to the first experimental example. In addition, Table 2 below illustrates the SCE and SCI reflectance (Y) and color coordinates (a*b*) of black of the display panel samples 1 to 4.

TABLE 2

| | | | Color | Color |
|---|---|---|---|---|
| | | | Coordinate | Coordinate |
| | | Reflectance (Y) | (a*) | (b*) |
| Sample 1 | SCI | 8.00 | — | — |
| Sample 2 | | 7.99 | — | — |
| Sample 3 | | 7.81 | — | — |
| Sample 4 | | 7.97 | — | — |
| Sample 1 | SCE | 0.95 | 5.92 | −5.90 |
| Sample 2 | | 0.97 | 5.86 | −6.21 |
| Sample 3 | | 0.88 | 5.72 | −5.79 |
| Sample 4 | | 0.91 | 6.01 | −6.20 |

Referring to FIGS. 25 and 26 and Table 2, compared to samples 1, 2, and 4 in which the protrusions were formed abnormally or not, in sample 3, in which the protrusions were formed normally, the SCI and SCE reflectance were reduced, and the black color was also improved by about 0.3 in the a* value and by about 0.4 in the b* value.

Through these results, it was confirmed that by forming the plurality of protrusions in the non-light emitting area, the reflectance may be reduced and the black color may be improved.

### <Second Manufacturing Example: Manufacturing of Display Panel>

Display panel samples illustrated in FIG. 18 were manufactured. In Samples 6 and 7, the width and spacing of the mask pattern for manufacturing the protrusions on the touch insulating layer and the color filter were manufactured as illustrated in Table 3 below, and in Sample 5, no protrusions were formed. Other structures were manufactured identically.

TABLE 3

| | Patten Width (μm) | Patten Spacing (μm) |
|---|---|---|
| Sample 5 | — | — |
| Sample 6 | 1.2 | 1.2 |
| Sample 7 | 1.6 | 1.6 |

### <Second Experimental Example: Reflectance Measurement>

The reflectance and reflection color of black of display panel samples 5 to 7 were measured. The reflectance was measured using the Specular Component Excluded (SCE) method, which measures reflected light with regular reflected light removed.

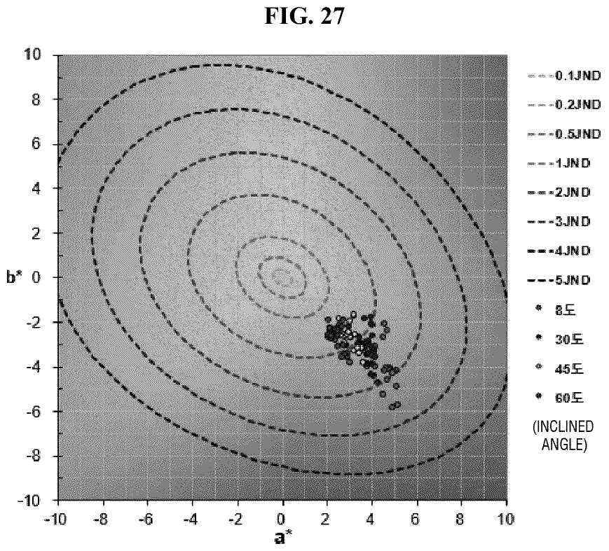

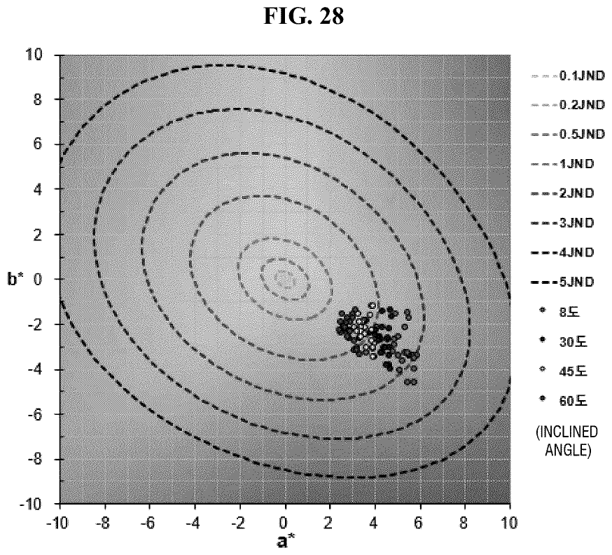

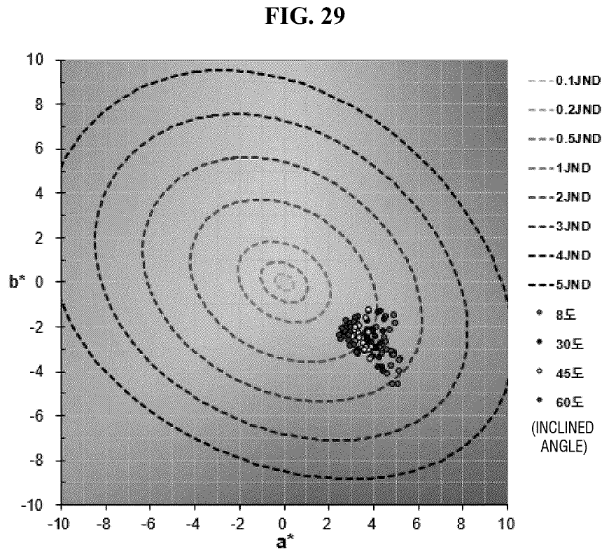

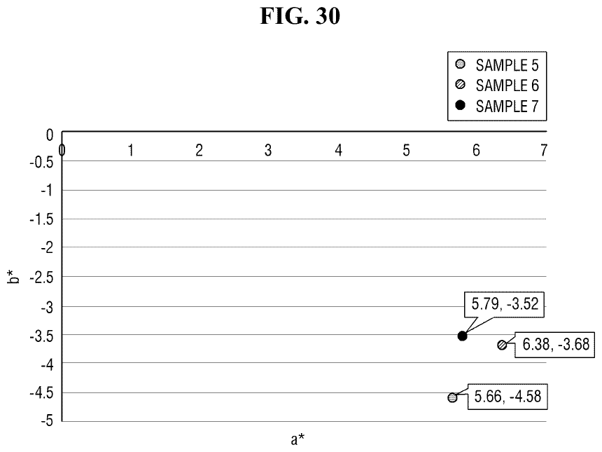

FIG. 27 is a graph illustrating an SCE color coordinate system of a display panel sample 5 according to a second experimental example, FIG. 28 is a graph illustrating an SCE color coordinate system of a display panel sample 6 according to the second experimental example, and FIG. 29 is a graph illustrating an SCE color coordinate system of a display panel sample 7 according to the second experimental example. FIG. 30 is a graph illustrating a reflection color of black of display panel samples 5 to 7 according to the second experimental example. In addition, Table 4 below illustrates the average color difference and chroma value for each SCE azimuth of the display panel samples 5 to 7.

TABLE 4

| | | | Sample 5 | Sample 6 | Sample 7 |
|---|---|---|---|---|---|
| SCE | ΔE′00 | 8° | 7.28(5.14/4.48/−3.92) | 7.66(5.02/5.2/−3.16) | 7.15(4.82/4.71/−3.1) |
| | (L*/a*/b*) | | | | |
| | *Average | 45° | 5.26(3.73/3.09/−2.73) | 5.61(3.55/3.62/−2.34) | 5.49(3.5/3.5/−2.39) |
| | Color | | | | |
| | Difference for | 60° | 4.5(3.13/2.44/−2.67) | 4.68(2.85/2.85/−2.3) | 4.83(2.9/2.96/−2.38) |
| | Each Azimuth | | | | |
| | Chroma | — | 3.78/2.24/1.86 | 3.11/2.29/1.97 | 3.11/2.16/1.72 |
| | (Δa*b*) | | | | |
| | *8°/45°/60° | | | | |

Referring to FIGS. 27 to 29 and Table 4, compared to samples 5 and 6 in which the protrusions were abnormally formed or not formed, in sample 7, in which the protrusions were formed normally, the b* value of the average color difference for each SCE azimuth was improved by about 0.3 to about 0.8.

In addition, referring to FIG. 30, compared to samples 5 and 6 in which the protrusions were abnormally formed or not formed, in sample 7, in which the protrusions were formed normally, the b* value of black color was improved by about 1.

Through these results, it was confirmed that bluish color and black color could be improved by forming an uneven portion including a plurality of protrusions on the touch insulating layer and the color filter in the non-light emitting area.

In concluding the detailed description, those skilled in the art will appreciate that many variations and modifications can be made to the embodiments without substantially departing from the principles of the present invention. Therefore, the disclosed embodiments of the invention are used in a generic and descriptive sense only and not for purposes of limitation.

What is claimed is:

1. A display device comprising:
a substrate comprising a display area and a non-display area adjacent to each other;
a pixel defining film which partitions a light emitting area and a non-light emitting area adjacent to each other within the display area;
a pixel electrode in the light emitting area and overlapped by the pixel defining film;
a light emitting layer on the pixel electrode;
a common electrode on the pixel defining film and the light emitting layer;
an encapsulation layer on the common electrode;
a reflection control layer on the encapsulation layer; and
an uneven portion defined by a layer of protrusions between the pixel defining film and the reflection control layer, the protrusions overlapping the non-light emitting area and non-overlapping the light emitting area.

2. The display device of claim 1, wherein the uneven portion is directly on the pixel defining film.

3. The display device of claim 1, wherein
the reflection control layer includes:
a color filter which overlaps the light emitting area, and
a light blocking layer including a light blocking pattern which overlaps the non-light emitting area and partitions a light exit opening of the light blocking layer which overlaps the light emitting area, and
the protrusions of the uneven portion further overlap the light exit opening of the light blocking layer.

4. The display device of claim 3, wherein
an overlapping area is defined where the light exit opening of the light blocking layer and the non-light emitting area overlap each other, and
the uneven portion is in the overlapping area and non-overlapping the light blocking pattern.

5. The display device of claim 1, wherein
each of the protrusions has a planar area in a plan view, and
the planar area decreases in a direction from the pixel defining film to the reflection control layer.

6. The display device of claim 1, wherein among the protrusions within the uneven portion, each of a pitch between adjacent protrusions and a width of each protrusion is about 0.5 micrometer to about 2 micrometers.

7. The display device of claim 2, further comprising a spacer between the pixel defining film and the common electrode, the spacer being coplanar with the layer of protrusions, overlapping the non-light emitting area and having a thickness along a thickness direction of the display device,
wherein a thickness of each protrusion is smaller than the thickness of the spacer.

8. The display device of claim 7, wherein the thickness of each protrusion is smaller than the thickness of the spacer by about 1 micrometer or more.

9. The display device of claim 7, wherein the protrusions and the spacer are respective patterns of a same material layer.

10. The display device of claim 2, wherein the pixel defining film defines the layer of protrusions of the uneven portion.

11. The display device of claim 1, wherein
the pixel defining film includes an inclined surface which defines the light emitting area and contacts the pixel electrode, and
the protrusions are arranged along the inclined surface.

12. The display device of claim 1, wherein
the encapsulation layer includes a first encapsulation layer, a second encapsulation layer on the first encapsulation layer, and a third encapsulation layer on the second encapsulation layer,
the first encapsulation layer and the third encapsulation layer include an inorganic material,
the second encapsulation layer includes an organic material, and
the second encapsulation layer defines the layer of protrusions of the uneven portion.

13. The display device of claim 1, further comprising a touch sensing layer between the encapsulation layer and the reflection control layer,
wherein
the touch sensing layer includes a touch electrode and a touch insulating layer, and
the touch insulating layer defines the layer of protrusions of the uneven portion.

14. The display device of claim 2, further comprising a touch sensing layer between the encapsulation layer and the reflection control layer.

15. A display device comprising:
a substrate comprising a display area and a non-display area adjacent to each other;
a pixel defining film which partitions a light emitting area and a non-light emitting area adjacent to each other within the display area;
a pixel electrode in the light emitting area and overlapped by the pixel defining film;
a light emitting layer on the pixel electrode;
a common electrode on the pixel defining film and the light emitting layer;
an encapsulation layer on the common electrode; and
a touch sensing layer on the encapsulation layer, the touch sensing layer including:
a touch insulating layer, and
a first uneven portion including a layer of first protrusions, the first protrusions overlapping the non-light emitting area and non-overlapping the light emitting area.

16. The display device of claim 15, wherein the first uneven portion of the touch sensing layer further includes:
a first groove overlapping the non-light emitting area, and
the first protrusions arranged along the first groove.

17. The display device of claim 16, wherein the first uneven portion of the touch sensing layer surrounds the light emitting area in a plan view.

18. The display device of claim 15, wherein the touch insulating layer defines the first protrusions.

19. The display device of claim 15, further comprising a color filter layer on the touch sensing layer, the color filter layer including a light blocking pattern which overlaps the non-light emitting area and a color filter which overlaps the light emitting area.

20. The display device of claim 19, wherein
the first uneven portion of the touch sensing layer further includes:
a first groove overlapping the non-light emitting area, and
the first protrusions arranged along the first groove, and
the color filter further includes a second uneven portion including:
a second groove overlapping the first groove, and
second protrusions arranged along the second groove and overlapping the first protrusions.

21. The display device of claim 20, wherein
a width of the second groove is smaller than a width of the first groove,
a depth of the second groove is smaller than a depth of the first groove,
a width of each of the second protrusions is greater than a width of each of the first protrusions, and
a height of each of the second protrusions is smaller than a height of each of the first protrusions.

22. The display device of claim 15, further comprising a polarizing member on the touch sensing layer.
